(19) United States
(12) Patent Application Publication
(10) Pub. No.: US 2026/0215112 A1
(43) Pub. Date: Jul. 23, 2026

(54) DISPLAY PANEL AND ELECTRONIC APPARATUS INCLUDING THE SAME

(71) Applicant: Samsung Display Co., Ltd., Yongin-si (KR)

(72) Inventors: Kitaek Jeong, Yongin-si (KR); Moosoon Ko, Yongin-si (KR); Jonghwan Shin, Yongin-si (KR); Yuri Oh, Yongin-si (KR); Kibok Yoo, Yongin-si (KR); Donghyeok Lee, Yongin-si (KR); Jongchan Lee, Yongin-si (KR); Yongseon Jo, Yongin-si (KR); Youngin Hwang, Yongin-si (KR)

(21) Appl. No.: 19/393,435

(22) Filed: Nov. 18, 2025

(30) Foreign Application Priority Data
Jan. 23, 2025 (KR) 10-2025-0010657

(51) Int. Cl. H10K 59/131

(52) U.S. Cl. CPC H10K 59/131

(57) ABSTRACT

A display panel and an electronic apparatus including the display panel are disclosed. The display panel may include a substrate having a through-hole, a first region outside the through-hole, and a second region outside the first region, a display element in the second region, a lower layer between the substrate and the display element, a first upper layer over the lower layer in the first region and having a first groove, and a first-1 metal layer over the lower layer and the first upper layer and in a direction to the through-hole with respect to a center of the first groove, wherein an end of the first-1 metal layer in the direction to the through-hole is over the lower layer, and an end of the first-1 metal layer in a direction to the center of the first groove protrudes from the first upper layer and is within the first groove.

### CROSS-REFERENCE TO RELATED APPLICATION

The present application claims priority to and the benefit of Korean Patent Application No. 10-2025-0010657, filed on Jan. 23, 2025, in the Korean Intellectual Property Office, the entire disclosure of which is incorporated herein by reference.

### BACKGROUND

### 1. Field

One or more embodiments of the present disclosure relate to a display panel and an electronic apparatus including the display panel. For example, one or more embodiments of the present disclosure relate to a display panel having a low defect rate and an electronic apparatus including the display panel.

### 2. Description of the Related Art

Display panels include a display area and a peripheral area outside (e.g., around or surrounding) the display area. In modern electronic apparatuses incorporating such display panels, the size of the display area continues to increase, and various functions are being integrated into these devices. Accordingly, research and development efforts have focused on display panels capable of accommodating various components within the display area, as well as on electronic apparatuses incorporating such panels.

However, in related art display panels and electronic apparatuses including such panels, defects frequently occur during the manufacturing process or during use, adversely affecting performance and reliability.

### SUMMARY

One or more embodiments of the present disclosure are directed toward a display panel having a low defect rate and an electronic apparatus including the display panel.

However, the above objective is just an example, and the scope of the present disclosure is not limited thereto.

Additional aspects of embodiments will be set forth in part in the description which follows and, in part, will be apparent from the description or may be learned by practice of the presented embodiments of the disclosure.

According to one or more embodiments, a display panel includes a substrate having a through-hole, a first region outside the through-hole, and a second region outside the first region, a display element arranged over the substrate so as to be in the second region (e.g., such that the display element is in the second region), a lower layer corresponding to the first region and the second region and arranged between the substrate and the display element, a first upper layer arranged over the lower layer in the first region and having a first groove, a first-1 metal layer arranged over the lower layer and the first upper layer so as to be in a direction to the through-hole (e.g., such that the first-1 metal layer is in a direction to the through-hole) with respect to a center of the first groove, wherein an end of the first-1 metal layer in the direction to the through-hole is arranged over the lower layer, and an end of the first-1 metal layer in a direction to the center of the first groove protrudes from the first upper layer and is within the first groove, and a first-2 metal layer arranged over the lower layer and the first upper layer so as to be in a direction to the second region (e.g., such that the first-2 metal layer is in a direction to the second region) with respect to the center of the first groove, wherein an end of the first-2 metal layer in the direction to the center of the first groove protrudes from the first upper layer and is within the first groove.

The first groove may be a groove closest to the through-hole among grooves in the first region.

The display panel may further include a second upper layer arranged over the lower layer in the first region, arranged between the second region and the first upper layer, and having a second groove, a second-1 metal layer arranged over the lower layer and the second upper layer so as to be in the direction to the through-hole (e.g., such that the second-1 metal layer is in the direction to the through-hole) with respect to the center of the second groove, wherein an end of the second-1 metal layer in a direction to a center of the second groove protrudes from the second upper layer and is within the second groove, a second-2 metal layer arranged over the lower layer and the second upper layer so as to be in the direction to the second region (e.g., such that the second-2 metal layer is in the direction to the second region) with respect to the center of the second groove, wherein an end of the second groove in the direction to the center of the second groove protrudes from the second upper layer and is within the second groove.

The first-2 metal layer and the second-1 metal layer may be integrally formed or provided as a single body.

The first-2 metal layer and the second-1 metal layer, which are integrally formed or arranged as the single body, may contact the lower layer between the first upper layer and the second upper layer.

A distance from an upper surface of the substrate to an upper surface of the first upper layer may decrease as measured moving from a part farther from the center of the first groove to the center of the first groove.

A distance from an upper surface of the substrate to an upper surface of the first upper layer at an end of the first upper layer in the direction to the center of the first groove may be less than a distance from the upper surface of the substrate to the upper surface of the first upper layer at an end of the first upper layer in a direction away from the first groove.

According to one or more embodiments, a display panel includes a substrate having a through-hole, a first region outside the through-hole, and a second region outside the first region, a display element arranged over the substrate so as to be in the second region (e.g., such that the display element is in the second region), a lower layer corresponding to the first region and the second region and arranged between the substrate and the display element, a first upper layer arranged over the lower layer in the first region and having a first opening exposing the lower layer, a first-1 metal layer arranged over the lower layer and the first upper layer so as to be in a direction to the through-hole (e.g., such that the first-1 metal layer is in a direction to the through-hole) with respect to a center of the first opening, wherein an end of the first-1 metal layer in the direction to the through-hole is arranged over the lower layer, and an end of the first-1 metal layer in a direction to the center of the first opening protrudes from the first upper layer and is within the first opening, and a first-2 metal layer arranged over the lower layer and the first upper layer so as to be in a direction to the second region (e.g., such that the first-2 metal layer is in a direction to the second region) with respect to the center of the first opening, wherein an end of the first-2 metal layer in the direction to the center of the first opening protrudes from the first upper layer and is within the first opening.

The first opening may be an opening closest to the through-hole among openings in the first region.

The display panel may further include a second upper layer arranged over the lower layer in the first region, arranged between the second region and the first upper layer, and having a second opening, a second-1 metal layer arranged over the lower layer and the second upper layer so as to be in the direction to the through-hole (e.g., such that the second-1 metal layer is in the direction to the through-hole) with respect to the center of the second opening, wherein an end of the second-1 metal layer in a direction to a center of the second opening protrudes from the second upper layer and is within the second opening, and a second-2 metal layer arranged over the lower layer and the second upper layer so as to be in the direction to the second region (e.g., such that the second-2 metal layer is in the direction to the second region) with respect to the center of the second opening, wherein an end of the second opening in the direction to the center of the second opening protrudes from the second upper layer and is within the second opening.

The first-2 metal layer and second-1 metal layer may be integrally formed or provided as a single body.

The first-2 metal layer and the second-1 metal layer, which are integrally formed or provided as a single body, may contact the lower layer between the first upper layer and the second upper layer.

A distance from an upper surface of the substrate to an upper surface of the first upper layer may decrease as measured moving from a part farther from the center of the first opening to the center of the first opening.

A distance from an upper surface of the substrate to an upper surface of the first upper layer at an end of the first upper layer in the direction to the center of the first opening may be less than a distance from the upper surface of the substrate to the upper surface of the first upper layer at an end of the first upper layer in a direction away from the first opening.

According to one or more embodiments, a display panel includes a substrate having a through-hole, a first region outside the through-hole, and a second region outside the first region, a display element arranged over the substrate so as to be in the second region (e.g., such that the display element is in the second region), a lower layer corresponding to the first region and the second region and arranged between the substrate and the display element, a first lower metal layer arranged over the lower layer in the first region, a first upper layer arranged over the first lower metal layer in the first region to cover an edge of the first lower metal layer, and having a first opening exposing a central portion of the first lower metal layer, a first-1 metal layer arranged over the lower layer and the first upper layer so as to be in a direction to the through-hole (e.g., such that the first-1 metal layer is in a direction to the through-hole) with respect to a center of the first opening, wherein an end of the first-1 metal layer in the direction to the through-hole is arranged over the lower layer, and an end of the first-1 metal layer in a direction to the center of the first opening protrudes from the first upper layer and is within the first opening, and a first-2 metal layer arranged over the first upper layer so as to be in a direction to the second region (e.g., such that the first-2 metal layer is in a direction to the second region) with respect to the center of the first opening, wherein an end of the first-2 metal layer in the direction to the center of the first opening protrudes from the first upper layer and is within the first opening.

The first opening may be an opening closest to the through-hole among openings in the first region.

The display panel may further include a second lower metal layer arranged over the lower layer in the first region and arranged between the second region and the first lower metal layer, wherein an edge of the second lower metal layer in a direction to the first lower metal layer is covered by the first upper layer, a second upper layer arranged over the lower layer in the first region to cover an edge of the second lower metal layer in the direction to the second region, wherein the second upper layer defines a space between the second upper layer and the first upper layer to expose a central portion of the second lower metal layer, and a second metal layer arranged over the second upper layer, wherein an end of the second metal layer in a direction to the space protrudes from the second upper layer and is within the space.

An end of the first-2 metal layer in the direction to the second region may protrude from the first upper layer and may be within the space.

A distance from an upper surface of the substrate to an upper surface of the first upper layer, in a portion where the upper surface of the first upper layer contacts the first-1 metal layer, may decrease as measured moving from a part farther from the center of the first opening to the center of the first opening.

According to one or more embodiments, an electronic apparatus includes a processor and the display panel configured to be controlled by the processor.

For example, the structural configuration or arrangement as described herein enables improved or enhanced electrical connectivity and mechanical reliability in the display panel by enhancing the arrangement and interaction of metal layers, insulating (e.g., electrically insulating) layers, and openings. By design controlling the vertical and lateral positioning of these elements—for example, around the through-hole and in the first and second regions—the design reduces stress concentrations and enhances layer adhesion. This contributes to a lower defect rate during manufacturing and operation, while also supporting the integration of additional components in compact form factors. As such, the disclosed display panel structure should particularly be well-suited for next-generation electronic apparatuses desiring or requiring high performance and durability.

Other aspects, features, and/or embodiments of the present disclosure will become better understood through the detailed description, the appended claims and equivalents thereof, and the accompanying drawings.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a perspective view schematically illustrating an electronic apparatus according to one or more embodiments;

FIG. 2 is an exploded perspective view schematically illustrating the electronic apparatus of FIG. 1;

FIG. 3 is a block diagram schematically illustrating the electronic apparatus of FIG. 1;

FIG. 4 is a plan view schematically illustrating a display panel according to one or more embodiments;

FIG. 5 is a side view schematically illustrating the display panel of FIG. 4;

FIG. 6 is a cross-sectional view of the display panel taken along the line A-A′ of FIG. 4;

FIG. 7 is a cross-sectional view of the display panel of FIG. 4 taken along the line perpendicular (e.g., substantially perpendicular) to the line A-A′ of FIG. 4;

FIG. 8 is a plan view schematically illustrating a display panel included in the electronic apparatus of FIG. 1;

FIG. 9 is an equivalent circuit diagram of a pixel circuit electrically connected to a light-emitting diode included in the display panel of FIG. 8;

FIG. 10 is a plan view schematically illustrating a portion of the display panel of FIG. 8;

FIG. 11 is a cross-sectional view schematically illustrating a cross-section taken along the line B-B′ of the display panel of FIG. 10;

FIG. 12 is an enlarged cross-sectional view illustrating a portion C of the display panel of FIG. 11;

FIG. 13 is a cross-sectional view schematically illustrating a portion of a display panel according to one or more embodiments;

FIG. 14 is a cross-sectional view schematically illustrating a portion of a display panel according to one or more embodiments;

FIG. 15 is an enlarged cross-sectional view illustrating a portion D of the display panel of FIG. 14;

FIG. 16 is a cross-sectional view schematically illustrating a portion of a display panel according to one or more embodiments;

FIG. 17 is a cross-sectional view schematically illustrating a portion of a display panel according to one or more embodiments;

FIG. 18 is an enlarged cross-sectional view illustrating a portion E of the display panel of FIG. 17; and

FIG. 19 is a cross-sectional view schematically illustrating a portion of a display panel according to one or more embodiments.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain the aspects and features of the present disclosure to those skilled in the art.

As the present disclosure allows for one or more suitable changes and embodiments, particular embodiments will be illustrated in the drawings and described in more detail in the written description. The aspects and features of embodiments of the present disclosure and methods of achieving the same will be more apparent with reference to one or more embodiments and drawings as described in more detail. The disclosure may, however, be embodied in one or more different forms and should not be construed as being limited to the embodiments set forth herein.

Hereinafter, one or more embodiments of the present disclosure will be described in more detail with reference to the accompanying drawings, and in the description with reference to the drawings, substantially the same or corresponding components are indicated by the same reference numerals and redundant descriptions thereof may not be provided.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the term “and/or” includes any and all combinations of one or more of the associated listed items.

Throughout the disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

In one or more embodiments, if (e.g., when) an element, such as a layer, a film, a region, or a plate, is referred to as being “on” or “above” another element, the element may be directly on or above the other element, or intervening elements may be present therebetween. In contrast, if (e.g., when) an element is referred to as being “directly on” or “directly above” another element, there are no intervening elements present therebetween.

Also, sizes of elements in the drawings may be exaggerated or reduced for convenience of descriptions. For example, because sizes and thicknesses of elements in the drawings are arbitrarily illustrated for convenience of descriptions, embodiments of the present disclosure are not limited thereto.

In one or more embodiments, the x-axis, the y-axis, and the z-axis are not limited to three axes of the rectangular coordinate system and may be interpreted in a broader sense. For example, the x-axis, the y-axis, and the z-axis may be perpendicular (e.g., substantially perpendicular) to one another or may represent different directions that are not perpendicular to one another.

In one or more embodiments, while the terms, such as “first,” “second,” and/or the like, are used to describe one or more suitable elements, these elements are not limited by these terms. These terms are only used to distinguish one element from another element. For example, without departing from the scope of the present disclosure, a first element, a first component, a first region, a first layer, or a first portion may be referred to as a second element, a second component, a second region, a second layer, or a second portion, and similarly, the second element, the second component, the second region, the second layer, or the second portion may be referred to as the first element, the first component, the first region, the first layer, or the first portion.

In one or more embodiments, the terms, such as “include,” “including,” “have,” and “having,” specify the presence of stated features or elements, but do not preclude the presence or addition of one or more other features or elements. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the present disclosure, the expression “A and/or B” represents A, B, or A and B. Also, the expression “at least one of A and B” represents A, B, or A and B.

In one or more embodiments, if (e.g., when) a layer, a region, or an element is referred to as being “connected to” another layer, region, or element, it may be directly or indirectly connected to the other layer, region, or element. For example, for example, intervening layers, regions, or elements may be present. For example, if (e.g., when) a layer, a region, or an element is referred to as being “electrically connected to” or “electrically coupled to” another layer, region, or element, it may be directly or indirectly electrically connected or coupled to the other layer, region, or element. For example, for example, intervening layers, regions, or elements may be present.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

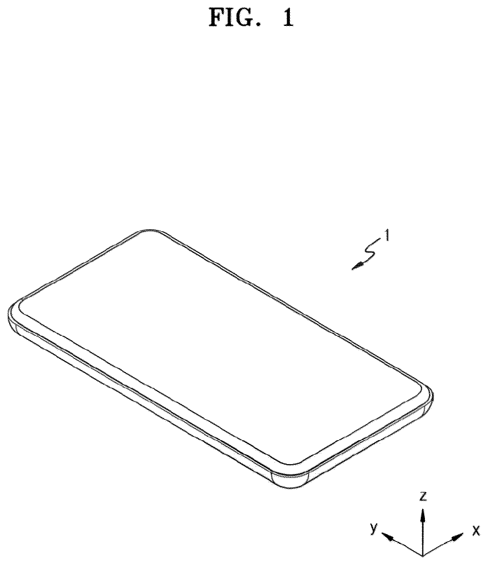

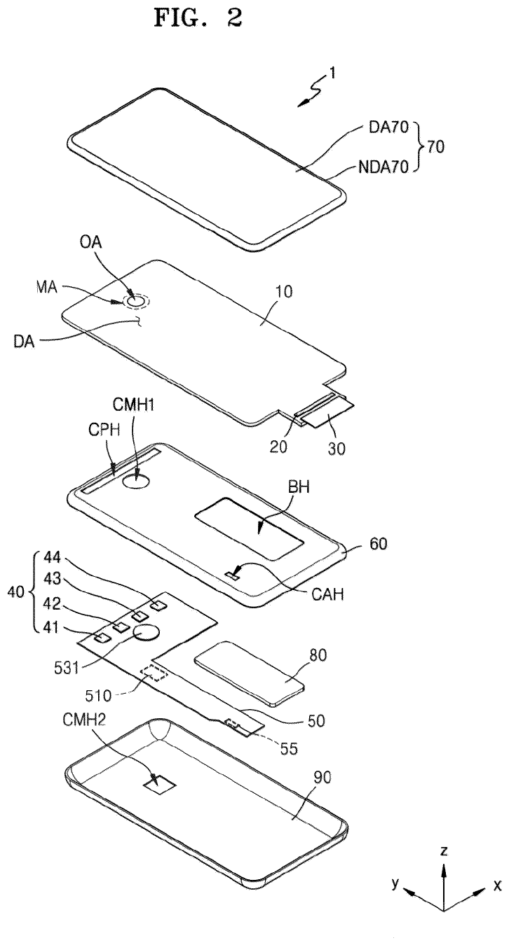

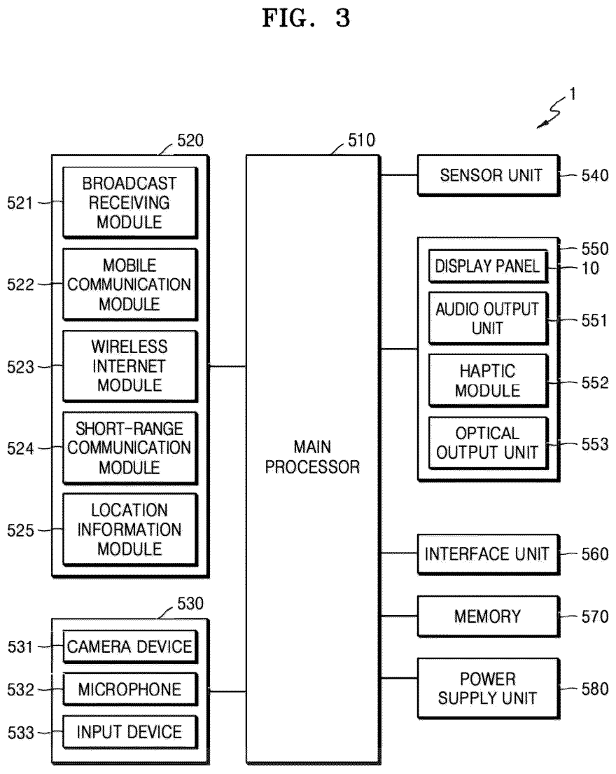

FIG. 1 is a perspective view schematically illustrating an electronic apparatus 1 according to one or more embodiments, FIG. 2 is an exploded perspective view schematically illustrating the electronic apparatus 1 of FIG. 1, and FIG. 3 is a block diagram schematically illustrating the electronic apparatus 1 of FIG. 1.

Referring to FIGS. 1 and 2, the electronic apparatus 1, which is a device to display moving images and/or still images, may be used in a portable electronic apparatus, such as a mobile phone, a smartphone, a tablet personal computer (PC), a mobile communication terminal, an electronic notebook, an electronic book, a portable multimedia player (PMP), a navigation, and/or an ultra mobile PC (UMPC), and/or may be one or more suitable products, such as televisions, laptops, monitors, billboards, and/or an internet of things (IoT)-linked device. The electronic apparatus 1 according to one or more embodiments may also be a wearable device, such as a smart watch, a watch phone, a glasses-type (kind) display, and/or a head-mounted display (HMD). The electronic apparatus 1 according to one or more embodiments may also be an instrument panel of a vehicle, a center fascia of a vehicle and/or a center information display (CID) arranged on a dashboard, a room mirror display replacing a side view mirror of a vehicle, and/or a display arranged on the rear side of a front seat for entertainment of backseat passengers of a vehicle.

In FIGS. 1 and 2, for convenience of descriptions, the electronic apparatus 1 according to one or more embodiments is illustrated as a smartphone. The electronic apparatus 1 may include a cover window 70, a display panel 10, a data driver 20, a display circuit board 30, components 40, a bracket 60, a main circuit board 50, a battery 80, and/or a lower cover 90.

In plan view, “left”, “right”, “up”, and “down” indicate the direction if (e.g., when) looking at the display panel 10 from a vertical direction from the display panel 10. For example, “left” indicates a −x direction, “right” indicates a +x direction, “up” indicates a +y direction, and “down” indicates a −y direction.

The electronic apparatus 1 may have an approximately or substantially rectangular shape in plan view. For example, the electronic apparatus 1 may have an approximately or substantially rectangular shape having a short side in the x-axis direction and a long side in the y-axis direction in the x-y plane, as illustrated in FIG. 1. A corner at which the short side in the x-axis direction meets the long side in the y-axis direction may be formed or arranged to have a round shape (e.g., a substantially round shape) with a certain (e.g., set or predetermined) curvature or formed or arranged to be a right angle (e.g., a substantially right angle). The planar shape (e.g., the substantially planar shape) of the electronic apparatus 1 is not limited to a rectangular shape (e.g., a substantially rectangular shape) and may include other polygonal (e.g., substantially polygonal), elliptical (e.g., substantially elliptical), or irregular shapes.

The cover window 70 may be arranged over the display panel 10 to cover an upper surface of the display panel 10. The cover window 70 as described in one or more embodiments may be to function to protect the upper surface of the display panel 10.

The cover window 70 may include a transparent cover unit DA70 corresponding to the display panel 10 and a light-shielding cover unit NDA70 around (e.g., surrounding) the transparent cover unit DA70. Light from the display area DA of the display panel 10 may be to pass through the transparent cover unit DA70 and proceed to the outside. The light-shielding cover unit NDA70 may include an opaque material (e.g., a colored opaque material) that blocks light. The light-shielding cover unit NDA70 may include a pattern that is visible to the user if (e.g., when) no image is displayed.

The cover windows 70 may include glass and/or plastic. If (e.g., when) the cover window 70 includes glass, the cover window 70 may include ultra-thin glass. If (e.g., when) the cover window 70 includes plastic, the cover window 70 may include polyethersulfone, polyacrylate, polyether imide, polyethylene naphthalate, polyethylene terephthalate, polyphenylene sulfide, polyarylate, polyimide, polycarbonate, and/or cellulose acetate propionate.

The display panel 10 may be arranged below the cover window 70. The display panel 10 may overlap the transparent cover unit DA70 of the cover window 70. The display panel 10 may include a display area DA. The display area DA is an area where an image may be displayed. The display area DA may include an area (hereinafter, component area) that is to transmit light emitted from a component 40 or a camera 531 arranged below the display panel 10 or transmit light proceeding toward the component 40 or the camera 531. In one or more embodiments, the display area DA may be referred to as being outside the component area to be around (e.g., surround) the component area. The component 40 may include a sensor that uses visible light, infrared light, sound, and/or the like.

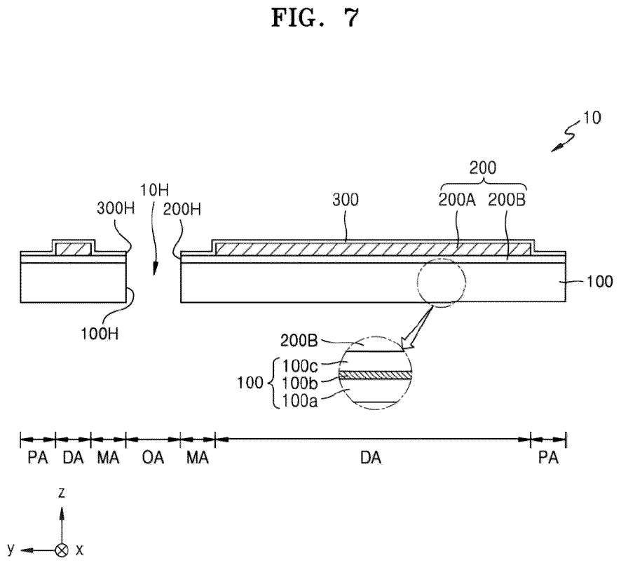

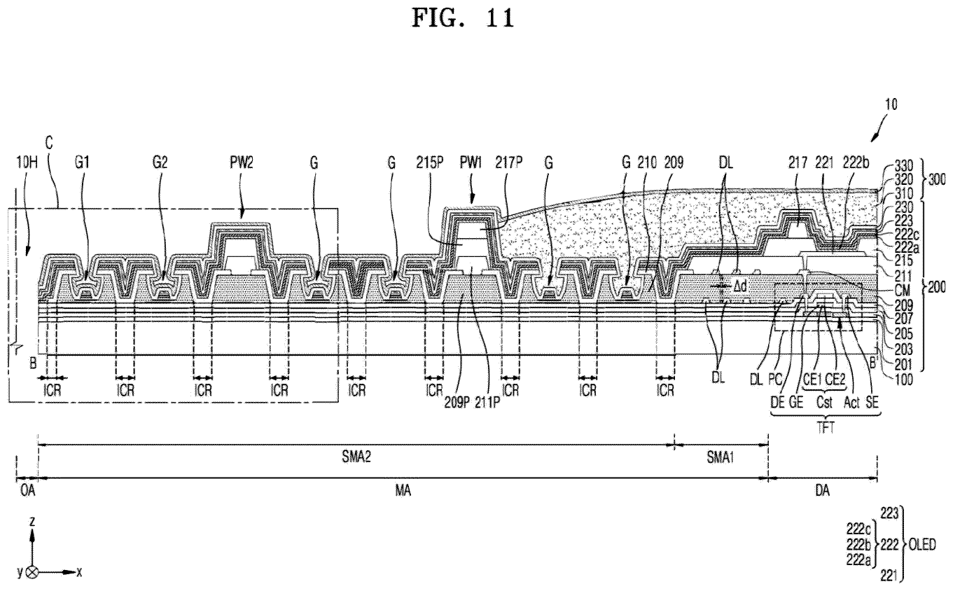

An opening area OA may be in the display area DA. The opening area OA may be defined by an opening defined in a substrate 100 (see FIGS. 7 and 11) included in the display panel 10. The opening area OA may be in the upper center of the display area DA as illustrated in FIG. 2, and the display area DA outside the opening area OA may have a shape that is around (e.g., surrounds) the opening area OA. The opening area OA may be in the display area DA in one or more suitable manners. For example, the opening area OA may be at the upper left side of the display area DA or at the upper right side of the display area DA. Although FIG. 2 illustrates that one opening area OA is within the display area DA, the display panel 10 may have a plurality of opening areas OA.

The component area as described in one or more embodiments may be or include an opening area OA as described in one or more embodiments. FIG. 2 illustrates that the location of the opening area OA corresponds to the location of the camera 531 arranged below the display panel 10. For example, in plan view, the opening area OA may overlap the camera 531. In one or more embodiments, the location of the opening area OA may correspond to the location of at least a part of the component 40, if (e.g., when) necessary or desired. For example, in plan view, the opening area OA may overlap at least one selected from among the first component 41, the second component 42, the third component 43, and the fourth component 44 included in the component 40. Hereinbelow, for convenience of descriptions, it may be described that the location of the opening area OA corresponds to the location of the camera 531 arranged below the display panel 10.

An intermediate area MA, which may be referred to as a first area, may be between the display area DA and the opening area OA. For example, the intermediate area MA, which may be referred to as the first area, may be outside the opening area OA. The intermediate area MA may have a closed loop shape (e.g., a substantially closed loop shape) being entirely (e.g., substantially entirely) around (e.g., entirely (e.g., substantially entirely) surrounding) the opening area OA in plan view. The display area DA may be referred to as a second area outside the first area.

The display panel 10 may be a light-emitting display panel including a light-emitting diode. The light-emitting diode may be an organic light-emitting diode (OLED) including an organic light-emitting layer and/or an inorganic light-emitting diode including an inorganic material. The inorganic light-emitting diode may include a PN diode including inorganic semiconductor-based materials. If (e.g., when) a voltage is applied in a forward direction to a PN junction diode, holes and electrons may be injected, and energy generated by recombination of the holes and electrons may be converted into light energy, to emit light of a certain (e.g., set or predetermined) color. The inorganic light-emitting diode as described in one or more embodiments may have a width of (about) several micrometers to (about) several hundred micrometers. The inorganic light-emitting diodes may be referred to as micro light-emitting diodes (LEDs).

The display panel 10 may be a rigid display panel that is rigid and is not easily or substantially bendable or a flexible display panel that is easily or substantially bendable, foldable, and/or rollable. For example, the display panel 10 may be a foldable display panel, a curved display panel with a curved display surface, a bended display panel in which an area other than a display surface is bent, a rollable display panel that may be rolled or unrolled, or a stretchable display panel.

The display panel 10 may be a transparent (e.g., substantially transparent) display panel that allows an object or background in a rear side of the display panel 10 to be visible from a front side of the display panel 10. In one or more embodiments, the display panel 10 may be a reflective display panel capable of reflecting light from an object in front of the display panel 10 or light from the background in the rear side of the display panel 10.

The data driver 20 may be mounted on the display panel 10 in the form of an integrated circuit (IC). In one or more embodiments, the data driver 20 may be arranged on the display circuit board 30.

The display circuit board 30 may be affixed to one side of the display circuit board 30. The display circuit board 30 may be a flexible printed circuit board (FPCB) that may be bent, a rigid printed circuit board (PCB) that is hard and is not easily or substantially bendable or a composite printed circuit board including both (e.g., simultaneously) an FPCB and a rigid PCB. A touch sensor driving unit may be mounted on the display circuit board 30. The touch sensor driving unit may be formed or arranged as an IC. The touch sensor driving unit may be electrically connected to touch electrodes of a touch screen layer of the display circuit board 30 through the display circuit board 30.

The touch screen layer of the display panel 10 may be to detect a user's touch input by using at least one of one or more suitable touch methods, such as a resistive film method and/or an electrostatic capacitance method. If (e.g., when) the touch screen layer of the display panel 10 detects a user's touch input in an electrostatic capacitive manner, the touch sensor driving unit may apply driving signals to driving electrodes of the touch electrodes and detect, through sensing electrodes of the touch electrodes, voltages due to mutual electrostatic capacitances (hereinafter, referred to as “mutual capacitance”) between the driving electrodes and the sensing electrodes, thereby determining whether a user's touch is received.

The user's touch may include a contact touch and a proximity touch. The contact touch indicates that a user's finger or an object, such as a pen, is in direct contact with the cover window 70 arranged on the touch screen layer. The proximity touch indicates that a user's finger or an object, such as a pen, is close to the cover window 70, such as by hovering. The touch sensor driving unit may be to transmit sensor data to a main processor 510 according to the detected voltages, and the main processor 510 may be to analyze the sensor data and calculate touch coordinates at which a touch input has occurred.

A control unit to supply driving voltages for driving pixels of the display panel 10, a gate driver, and the data driver 20 may be arranged on the display circuit board 30.

The bracket 60 to support the display panel 10 may be arranged below the display panel 10. The bracket 60 may include plastic, metal, or both (e.g., simultaneously) plastic and metal. The bracket 60 may have a first camera hole CMH1 into which the camera 531 is inserted, a battery hole BH in which the battery 80 is arranged, a cable hole CAH through which a cable connected to the display circuit board 30 passes, and a component hole CPH corresponding to components 40. The component hole CPH may overlap the components 40 of the main circuit board 50 if (e.g., when) viewed from a third direction (z-axis direction). For reference, the display area DA of the display panel 10 may overlap the components 40 of the main circuit board 50 if (e.g., when) viewed from the third direction (z-axis direction). In one or more embodiments, the bracket 60 may not have a component hole (CPH).

The components 40 of the electronic apparatus 1 may include a first component 41, a second component 42, a third component 43, and a fourth component 44 which overlap the display panel 10. Each of the first component 41, the second component 42, the third component 43, and the fourth component 44 may include at least one selected from among a proximity sensor, an illumination sensor, an iris sensor, a face recognition sensor, and a camera (or image sensor). The proximity sensor utilizing infrared rays may be to detect an object arranged close to an upper surface of the electronic apparatus 1, and the illumination sensor may be to detect a brightness of light incident on the upper surface of the electronic apparatus 1. In one or more embodiments, the iris sensor may be to image a person's iris over the upper surface of the electronic apparatus 1, and the camera may be to image an object arranged over the upper surface of the electronic apparatus 1. The components 40 are not limited to a proximity sensor, an illumination sensor, an iris sensor, a face recognition sensor, and a camera and may include one or more suitable sensors.

The main circuit board 50 and the battery 80 may be arranged below the bracket 60. The main circuit board 50 may be a printed circuit board or a FPCB.

The main circuit board 50 may include the main processor 510, the camera 531, a main connector 55, and the components 40. The main processor 510 may be formed or arranged as an IC. If (e.g., when) necessary or desired, the electronic apparatus 1 may include not only the camera 531 arranged over the upper surface of the main circuit board 50 but also a camera arranged below a lower surface of the main circuit board 50. Each of the main processor 510 and the main connector 55 may be arranged on either one selected from among the upper surface of the main circuit board 50 and the lower surface of the main circuit board 50. The main circuit board 50 may be electrically connected to the display circuit board 30 through the main connector 55 and/or the like.

The main processor 510 may be to control all (e.g., substantially all) functions of the electronic apparatus 1. For example, the main processor 510 may be to output digital video data to the data driver 20 so that (e.g., such that) an image is displayed on the display panel 10. The main processor 510 may control the display panel 10 like in this way or in other ways. The main processor 510 may be to receive an input of sensing data from the touch sensor driving unit. The main processor 510 may be to determine whether a user's touch is received according to the sensing data and execute an operation corresponding to a direct touch or proximity touch of the user. The main processor 510 may be an application processor, a central processing unit, or a system chip, each of which include an IC.

The camera 531 may be to process image frames of a still image, a moving image, and/or the like obtained by an image sensor in a camera mode and output the processed image frames to the main processor 510. The camera 531 may include at least one of a camera sensor (e.g., charge-coupled device (CCD), complementary metal-oxide-semiconductor (CMOS), and/or the like), a photo sensor (or image sensor), or a laser sensor.

A cable 35, which passes through the cable hole CAH defined in the bracket 60, may be connected to the main connector 55, and thus the main connector 55 may be electrically connected to the display circuit board 30.

The electronic apparatus 1 may be represented by a block diagram as illustrated in FIG. 3. The electronic apparatus 1 may be represented as including, in addition to the main processor 510, a wireless communication unit 520, an input unit 530, a sensor unit 540, an output unit 550, an interface unit 560, a memory 570, and/or a power supply unit 580 as illustrated in FIG. 3.

The wireless communication unit 520 may include at least one of a broadcast receiving module 521, a mobile communication module 522, a wireless internet module 523, a short-range communication module 524, or a location information module 525.

The broadcast receiving module 521 may be to receive broadcast signals and/or broadcast-related information from an external broadcast management server via a broadcast channel. The broadcast channel may include satellite channels and/or terrestrial channels.

The mobile communication module 522 may be to transmit and receive wireless signals to and from at least one of an external terminal, a server on a mobile communication network, or a base station established according to technology standards or communication methods for mobile communication (e.g., Global System for Mobile Communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), and Long Term Evolution-Advanced (LTE-A)). The wireless signal may include voice call signals, video call signals, and/or one or more suitable forms of data according to text/multimedia message transmission and reception.

The wireless internet module 523 is a module for wireless internet connection. The wireless internet module 523 may be configured or arranged to transmit and receive wireless signals in a communication network according to wireless internet technologies. The wireless internet technology may include, for example, Wireless LAN (WLAN), Wireless-Fidelity (Wi-Fi), Wi-Fi Direct, Digital Living Network Alliance (DLNA), and/or the like.

The short-range communication module 524, which ensures short-range communication, may be to support short-range communication by utilizing at least one of Bluetooth, Radio Frequency Identification (RFID), Infrared Data Association (IrDA), Ultra Wideband (UWB), ZigBee, Near Field Communication (NFC), Wi-Fi, Wi-Fi Direct, or Wireless Universal Seral Bus (USB) technologies. The short-range communication module 524 may be to support wireless communication between the electronic apparatus 1 and a wireless communication system, between the electronic apparatus 1 and another electronic apparatus, and/or the electronic apparatus 1 and a network where another electronic apparatus (or external server) is arranged, through wireless area networks. The wireless area networks may be wireless personal area networks. The other electronic apparatus may be a wearable device capable of mutually exchanging data with (or linking with) the electronic apparatus 1.

The location information module 525, which is a module to obtain a location (or current location) of the electronic apparatus 1, may include a global positioning system (GPS) module and/or a Wi-Fi module.

The input unit 530 may include an image input unit, such as the camera 531 to input an image signal, an audio input unit, such as a microphone 532 to input an audio signal, and an input device 533 to receive information from a user. The camera 531 may be to process image frames, such as still images and/or moving images, obtained by an image sensor in a video call mode and/or shooting mode. The processed image frames may be displayed on the display panel 10 or stored in the memory 570. The microphone 532 may be to process external audio signals into electrical sound data. The processed sound data may be suitably used according to a function being performed (or application being run) in the electronic apparatus 1.

The main processor 510 may be to control an operation of the electronic apparatus 1 to correspond to information received via the input device 533. The input device 533 may include a touch input means and/or a mechanical input means, such as a button on the rear surface and/or side surface of the electronic apparatus 1, a dome switch, a jog wheel, and/or a jog switch. The touch input means may include a touch screen layer of the display panel 10.

The sensor unit 540 may include one or more sensors configured or arranged to sense at least one of information within the electronic apparatus 1, being around (e.g., surrounding) environment information of the electronic apparatus 1, or user information, and generate a sensing signal corresponding thereto. Based on this sensing signal, the main processor 510 may control driving or operation of the electronic apparatus 1 or perform data processing, functions, or operations associated with applications installed in the electronic apparatus 1. The sensor unit 540 may be a proximity sensor, an illumination sensor, or a facial recognition sensor as described in one or more embodiments with respect to the components 40. The sensor unit 540 may include an acceleration sensor, a magnetic sensor, a G-sensor, a gyroscope sensor, a motion sensor, an RGB sensor, an infrared (IR) sensor, a finger scan sensor, an ultrasonic sensor, an optical sensor, and/or a battery gauge. In one or more embodiments, the sensor unit 540 may include an environmental sensor and/or a chemical sensor. The environmental sensors may include, for example, a barometer, a hygrometer, a thermometer, a radiation detection sensor, a heat detection sensor, and/or a gas detection sensor. The chemical sensors may include, for example, an electronic nose, a healthcare sensor, and/or a biometric recognition sensor.

The output unit 550 may be to generate an output associated with vision, hearing, and/or tactile sensations and may include at least one of the display panel 10, an audio output unit 551, a haptic module 552, or an optical output unit 553.

The display panel 10 may be configured or arranged to display (output) information processed in the electronic apparatus 1. For example, the display panel 10 may be configured or arranged to display execution screen information of an application driven in the electronic apparatus 1 or to display user interface (UI) or graphic user interface (GUI) information according to the execution screen information. The display panel 10 may include a display layer to display images and/or a touch screen layer to detect a touch input of a user. Therefore, the display panel 10 may be to function as one of the input devices 533 that provide an input interface between the electronic apparatus 1 and the user, and at the same time (e.g., concurrently), may be to function as the output unit 550 that provides an output interface between the electronic apparatus 1 and the user.

The audio output unit 551 may be to output audio data received from the wireless communication unit 520 or stored in the memory 570 in a call signal reception mode, a call mode, a recording mode, a speech recognition mode, a broadcast reception mode, and/or the like. The audio output unit 551 may be to output audio signals associated with functions performed in the electronic apparatus 1, such as call signal reception sound, message reception sound, and/or the like. The audio output unit 551 may include a receiver and/or a speaker. At least one of the receiver or the speaker may be a sound generation device that is attached below the display panel 10 and vibrates the display panel 10 to output sound. The sound generation device may be a piezoelectric element, piezoelectric actuator, that contracts and expands in response to an electric signal, or an exciter that generates a magnetic force by using a voice coil and vibrates the display panel 10.

The haptic module 552 may be to generate one or more suitable tactile effects that may be felt by the user. The haptic module 552 may be to provide vibration to the user as a tactile effect. The haptic module 552 may not only transfer a tactile effect through direct contact, but also may be implemented such that the user may feel the tactile effect through muscle senses of the fingers or arms.

The optical output unit 553 may be to output a signal to notify the occurrence of an event by utilizing light from a light source. Examples of events occurring in the electronic apparatus 1 may include receiving a message, receiving a call signal, receiving a missed call, an alarm, a schedule alarm, a schedule reminder, receiving an e-mail, receiving information through an application, and/or the like. The signal output from the optical output unit 553 may be implemented as the electronic apparatus 1 emits light of a single color or a plurality of colors from the front or rear thereof. The outputting of the signal may be terminated if (e.g., when) the electronic apparatus 1 detects the user's identification of the event.

The interface unit 560 may be to serve as a passageway for one or more suitable types (kinds) of external devices connected to the electronic apparatus 1. The interface unit 560 may include at least one of a wired/wireless headset port, an external charger port, a wired/wireless data port, a memory card port, a port connecting a device equipped with an identification module, an audio input/output (I/O) port, a video I/O port, or an earphone port. If (e.g., when) the electronic apparatus 1 is connected to an external device through the interface unit 560, the electronic apparatus 1 may perform an appropriate or suitable control associated with the connected external device.

The memory 570 may be to store data supporting one or more suitable functions of the electronic apparatus 1. The memory 570 may be to store a plurality of application programs running on the electronic apparatus 1, data for an operation of the electronic apparatus 1, and instructions. At least one or more of the plurality of applications may be downloaded from an external server through wireless communication. The memory 570 may be to store an application for an operation of the main processor 510 or may temporarily be to store input/output data, e.g., data, such as a phonebook, messages, still images, and/or moving images. In one or more embodiments, the memory 570 may be to store haptic data for vibration of one or more suitable patterns provided to the haptic module 552 and audio data associated with one or more suitable sounds provided to the audio output unit 551.

The memory 570 may include a storage medium of at least one type (kind) selected from among a flash memory type (kind), a hard disk type (kind), a solid state disk type (kind) (SSD) type (kind), a silicon disk drive (SDD) type (kind), a multimedia card micro type (kind), a card-type (kind) memory (e.g., secure digital (SD) memory and/or extreme digital (XD) memory), random access memory (RAM), static RAM (SRAM), read-only memory (ROM), electrically erasable programmable ROM (EEPROM), programmable ROM (PROM), magnetic memory, a magnetic disk, or an optical disk.

Under the control of the main processor 510, the power supply unit 580 may be to receive external power and/or internal power and supply power to each of elements included in the electronic apparatus 1. The power supply unit 580 may include the battery 80. In one or more embodiments, the power supply unit 580 may have a connection port, and the connection port may be configured or arranged as an example of the interface unit 560 to which an external charger supplying power for battery charging is electrically connected. In one or more embodiments, the power supply unit 580 may be configured or arranged to charge the battery 80 in a wireless manner. The battery 80 may be arranged not to overlap the main circuit board 50 in the third direction (z-axis direction). The battery 80 may overlap the battery hole BH of the bracket 60.

The lower cover 90 may form the exterior of the electronic apparatus 1 and may have an opening portion that exposes a portion of the display panel 10. The lower cover 90 may be assembled with the display panel 10 such that the display area of the display panel 10 is exposed through the opening portion of the lower cover 90. The lower cover 90 may be arranged such that the display panel 10 is between the lower cover 90 and the cover window 70. The lower cover 90 may be arranged below the main circuit board 50 and the battery 80. The lower cover 90 may be fastened and fixed to the bracket 60. The lower cover 90 may form the exterior shape of a lower part of the electronic apparatus 1. The lower cover 90 may include plastic, metal, or both (e.g., simultaneously) plastic and metal.

A second camera hole CMH2 through which a lower surface of the camera 531 is exposed may be formed or arranged in the lower cover 90. A location of the camera 531 and positions of the first and second camera holes CMH1 and CMH2 corresponding to the camera 531 are not limited to the embodiments as illustrated in FIGS. 1 and 2 and may be suitably modified.

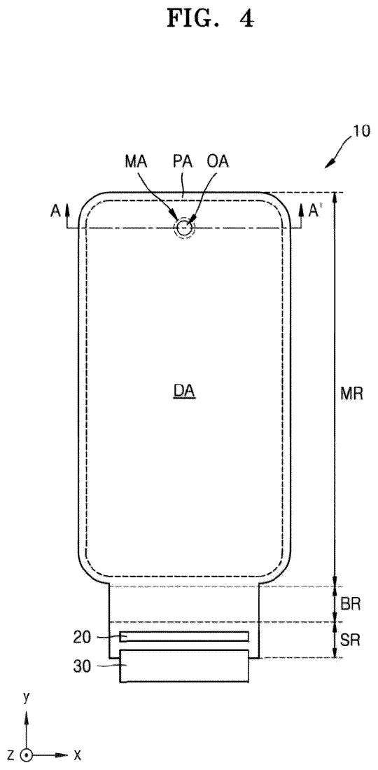

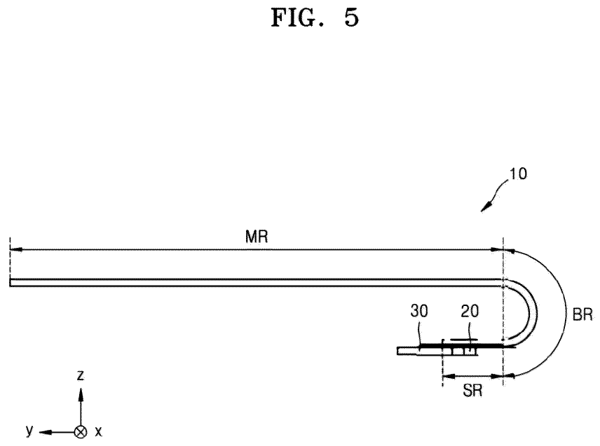

FIG. 4 is a plan view schematically illustrating the display panel 10 according to one or more embodiments, and FIG. 5 is a side view schematically illustrating the display panel 10 of FIG. 4. The electronic apparatus 1 as described in one or more embodiments may include the display panel 10 as illustrated in FIGS. 4 and 5.

The display panel 10 may include the display area DA and a peripheral area PA outside the display area DA. The display area DA may be a portion in which an image is displayed, and a plurality of pixels may be arranged in the display area DA. The display area DA may have one or more suitable shapes, such as, for example, a circular shape (e.g., a substantially circular shape), an elliptical shape (e.g., a substantially elliptical shape), a polygonal shape (e.g., a substantially polygonal shape), and/or other specific (e.g., a set or predetermined) shape. FIG. 4 illustrates that the display area DA has an approximately or substantially rectangular shape with round corners.

The peripheral area PA may be arranged outside the display area DA. A width in the first direction (x-axis direction) of a portion of the peripheral area PA at the bottom of the display area DA and extending in the first direction (x-axis direction) may be smaller than a width of the display area DA in the first direction (x-axis direction). This structure may make it easy for at least a part of the peripheral area PA to be bent.

A planar shape (e.g., a substantially planar shape) of the display panel 10 as illustrated in FIG. 4 may be substantially identical to a shape of a substrate 100 included in the display panel 10. If (e.g., when) it is described that the display panel 10 includes the display area DA and the peripheral area PA outside the display area DA, it may indicate that the substrate 100 includes the display area DA and the peripheral area PA outside the display area DA. Hereinbelow, for convenience of descriptions, it is described that the substrate 100 includes the display area DA and the peripheral area PA.

The display panel 10 may include a main area MR, a bending area BR outside the main area MR, and a sub-area SR spaced and/or apart (e.g., spaced apart or separated) from the main area MR with the bending area BR therebetween. The main area MR may be arranged at one side of the bending area BR, and the sub-area SR may be arranged on the other side of the bending area BR. The display panel 10 may be bent in the bending area BR, as illustrated in FIG. 5, and if (e.g., when) viewed from the third direction (e.g., a z-axis direction), at least part of the sub-area SR may overlap the main area MR. FIG. 5 illustrates that the display panel 10 is bent, but embodiments of the present disclosure are not limited thereto. For example, the display panel 10 may be a foldable display panel, and the display panel 10 may be bent with respect to a bending axis crossing the display area DA. In one or more embodiments, the display panel 10 may not be bent. The sub-area SR may be a non-display area.

The data driver 20 may be arranged in the sub-area SR of the display panel 10. The data driver 20 may be arranged on the display panel 10 in the form of an IC. For example, the data driver 20 may be a data driving IC to generate data signals.

The display circuit board 30 may be affixed to an end of the sub-area SR of the display panel 10. The display circuit board 30 may be electrically connected to the data driver 20 and/or the like through a pad of the sub-area SR of the display panel 10.

As described in one or more embodiments with reference to FIG. 2, the display panel 10 may have the opening area OA within the display area DA. And the display panel 10 may have the intermediate area MA between the display area DA and the opening area OA.

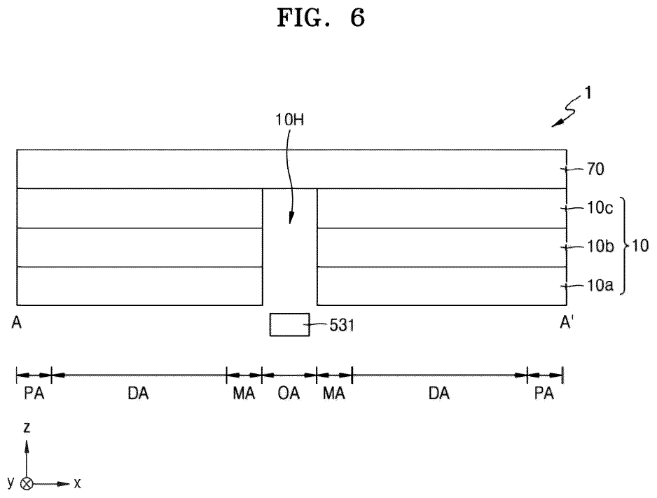

FIG. 6 is a cross-sectional view schematically illustrating a cross-section of the display panel 10 taken along the line A-A′ of FIG. 4. FIG. 6 illustrates not only the display panel 10 but also the cover window 70 and the camera 531 together, for convenience of illustrations. As described in one or more embodiments, the electronic apparatus 1 may include the display panel 10 and the camera 531 in the opening area OA of the display panel 10.

The display panel 10 may include an image generation layer 10a, an input detection layer 10b, and an optical function layer 10c.

The image generation layer 10a may include display elements (or light-emitting elements) that emit light to display an image. A display element may include a light-emitting diode, e.g., an OLED including an organic emission layer. The display element may also include an inorganic light-emitting diode including an inorganic material. The inorganic light-emitting diode may include a PN diode including inorganic semiconductor-based materials. If (e.g., when) a voltage is applied in a forward direction to a PN junction diode, holes and electrons may be injected, and energy generated by recombination of the holes and electrons may be converted into light energy, to emit light of a certain (e.g., set or predetermined) color. The inorganic light-emitting diode as described in one or more embodiments may have a width of (about) several micrometers to (about) several hundred micrometers or (about) several nanometers to (about) several hundred nanometers.

However, embodiments of the present disclosure are not limited thereto. For example, the image generation layer 10a may include a quantum dot layer. In this case, light which is generated from the light-emitting layer included in the image generation layer 10a and has a wavelength belonging to a set or predetermined wavelength band may be converted into light having a preset wavelength by the quantum dot layer.

The input detection layer 10b may be to obtain coordinate information according to an external input, such as a touch event. The input detection layer 10b may include sensing electrodes and/or touch electrodes and signal lines (e.g., trace lines) electrically connected to the sensing electrodes and/or touch electrodes. The input detection layer 10b may be to detect an external input through a mutual capacitance sensing method and/or a self-capacitance sensing method.

The input detection layer 10b may be arranged on the image generation layer 10a. The input detection layer 10b may be directly formed or arranged on the image generation layer 10a or may be formed or arranged separately and then attached to the image generation layer 10a through an adhesive layer, such as an optically transparent (e.g., substantially transparent) adhesive. In the former case, the input detection layer 10b may be formed or arranged continuously after the process of forming or arranging the image generating layer 10a, and in this case, the adhesive layer may not be between the input detection layer 10b and the image generating layer 10a. FIG. 6 illustrates that the input detection layer 10b is between the image generation layer 10a and the optical function layer 10c, however, one or more suitable modifications may be made to the structure. For example, the input detection layer 10b may be arranged on the optical function layer 10c.

The optical function layer 10c may include an anti-reflection layer. The anti-reflection layer may reduce the reflectivity (e.g., a degree of occurrence of the reflectivity) of light (external light) traveling from the outside toward the display panel 10 through the cover window 70. The anti-reflection layer may include a retardation film and a polarization film. In one or more embodiments, the anti-reflection layer may include a black matrix and/or color filters. In the latter case, the color filters may be arranged in consideration of the color of light emitted from the image generation layer 10a.

To improve or enhance the transmittance of the opening area OA, the display panel 10 may include a through-hole 10H. The through-hole 10H may penetrate the image generation layer 10a, the input detection layer 10b, and the optical function layer 10c.

The cover window 70 may be arranged over the display panel 10. The cover window 70 may be attached to the optical function layer 10c through an adhesive layer, such as a transparent (e.g., substantially transparent) optical clear adhesive (OCA). The cover window 70 may cover the through-hole 10H included in the display panel 10.

The opening area OA may be an area where the through-hole 10H of the display panel 10 is arranged. In response to this opening area OA, an electronic element, such as the camera 531 or the component 40, may be placed (in the-z direction of the display panel 10). For example, the electronic element may overlap the opening area OA in plan view. FIG. 6 illustrates that the camera 531 is arranged to correspond to the opening area OA as described in one or more embodiments. In one or more embodiments, at least a portion of the camera 531 may be within the through-hole 10H of the display panel 10.

FIG. 7 is a cross-sectional view schematically illustrating a cross-section taken along the line perpendicular (e.g., substantially perpendicular) to the line A-A′ of the display panel 10 of FIG. 4.

Referring to FIG. 7, the display panel 10 may include a display layer 200 and a thin film encapsulation layer 300 arranged on a substrate 100. The image generation layer 10a as described in one or more embodiments with reference to FIG. 6 may include the substrate 100, the display layer 200, and the thin film encapsulation layer 300.

The substrate 100 may include glass, metal, and/or a polymer resin. The substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have a multi-layer structure including two layers and an inorganic layer between the two layers, the two layers including the polymer resin as described in one or more embodiments. For example, as illustrated in an enlarged view portion of FIG. 7, the substrate 100 may include a first base layer 100a, an inorganic layer 100b, and a second base layer 100c. In one or more embodiments, the substrate 100 may have a structure in which the base layer and the inorganic layer are alternately stacked. The inorganic layer 100b may include silicon nitride, silicon oxide, and/or silicon oxynitride and may have a single-layer structure or a multi-layer structure. The inorganic layer 100b may act as a barrier layer that prevents the penetration (or reduces a degree or occurrence of the penetration) of impurities and/or external foreign substances.

The display layer 200 may have a plurality of pixels. The display layer 200 may include a display element layer 200A including a display element arranged for each pixel, and a pixel circuit layer 200B including a pixel circuit arranged for each pixel and insulating (e.g., electrically insulating) layers. The pixel circuit may include a thin film transistor and a storage capacitor, and the display element may include an organic light-emitting diode (OLED).

The thin film encapsulation layer 300 may cover the display layer 200. The thin film encapsulation layer 300 may include at least one inorganic encapsulation layer and at least one organic encapsulation layer. The thin film encapsulation layer 300 may prevent the penetration of impurities, such as moisture, from the outside into the display element (or reduce a degree or occurrence of the penetration of impurities, such as moisture, from the outside into the display element).

As described in one or more embodiments, the display panel 10 may include the through-hole 10H penetrating the display panel 10. The through-holes 10H may correspond to the opening area OA. FIG. 7 illustrates that the substrate 100 has a through-hole 100H, the display layer 200 has a through-hole 200H, and the thin film encapsulation layer 300 has a through-hole 300H, thereby forming or arranging the through-hole 10H penetrating the display panel 10.

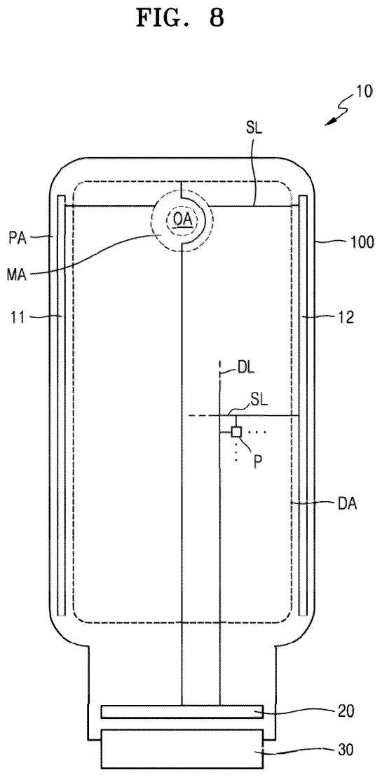

FIG. 8 is a plan view schematically illustrating the display panel 10 included in the electronic apparatus of FIG. 1. As illustrated in FIG. 8 and as described in one or more embodiments, the display panel 10 may include the opening area OA, the intermediate area MA that may be referred to as the first area, the display area DA that may be referred to as the second area, and a peripheral area PA. For example, the substrate 100 of the display panel 10 may include the through-hole corresponding to the opening area OA, the display area DA outside the through-hole to be around (e.g., surround) the through-hole, the intermediate area MA between the through-hole and the display area DA, and the peripheral area PA outside the display area DA.

The display panel 10 may include a plurality of pixels P in the display area DA, and the display panel 10 may be to display an image by using light emitted from the pixels P. Each of the pixels P may be to emit red, green, or blue light by utilizing a light-emitting diode. The pixels P may be electrically connected to a scan line SL and a data line DL.

In the peripheral area PA, scan drivers 11 and 12 to provide scan signals to each of pixels P, data drivers 20 to provide data signals to each of pixels P, a first power line (e.g., the driving voltage line) to provide the driving voltage to each of pixels P, and a second power line to provide a common voltage (e.g., second power voltage) to each of pixels P may be arranged.

The intermediate area MA may be around (e.g., surround) the opening area OA. The intermediate area MA may not have display elements, such as light-emitting diodes, that are to emit light. In one or more embodiments, a display element may also be in the intermediate area MA, and in this case, a pixel circuit electrically connected to the display element may be within the intermediate area MA or within the display area DA. Among the pixels P in the display area DA, one or more of signal lines that provide signals to pixels P relatively adjacent to the opening area OA may pass through the intermediate area MA.

For example, the data line DL may cross the display area DA, but a portion of the data line DL may bypass the through-hole 10H of the display panel 10 in the opening area OA, through the intermediate area MA along the edge of the through-hole 10H. FIG. 8 illustrates that data lines DL cross the display area DA along the y-axis direction, but one or more data lines DL detour to be partially around (e.g., partially surround) the opening area OA in the intermediate area MA.

Scan lines SL may cross the display area DA in an x-axis direction and may each include a first portion and a second portion spaced and/or apart (e.g., spaced apart or separated) from each other with the opening area OA therebetween. In this case, the first portion of the scan line SL on one side (in −x direction) of the opening area OA may be electrically connected to the scan driver 11 on one side (in −x direction) of the opening area OA, and the second portion of the scan line SL on the other side (in +x direction) of the opening area OA may be electrically connected to the scan driver 12 on the other side (in +x direction) of the opening area OA. Accordingly, the scan lines SL may not need to bypass the intermediate area MA to be partially around (e.g., partially surround) the opening area OA. If (e.g., when) the display panel 10 has only one scan driver, one or more scan lines SL may bypass the opening area OA to be partially around (e.g., partially surround) the opening area OA in the intermediate area MA.

For reference, FIG. 8 illustrates that the data driver 20 is arranged on the substrate 100 so as to be adjacent (e.g., such that the data drive 20 is adjacent) to one edge of the substrate 100 (in −y direction), but embodiments of the present disclosure are not limited thereto. For example, the data driver 20 may be arranged on a printed circuit board that is electrically connected to the display panel 10 through pads at one edge of the display panel 10. If (e.g., when) the data driver 20 is arranged on the substrate 100 so as to be adjacent (e.g., such that the data driver 20 is adjacent) to one edge of the substrate 100 (in −y direction) as illustrated in FIG. 8, a portion of the substrate 100 may be bent as described in one or more embodiments with reference to FIG. 5 so that (e.g., such that) the portion of the substrate 100 where the data driver 20 and/or the like is arranged may overlap the display area DA and may be behind the display area DA.

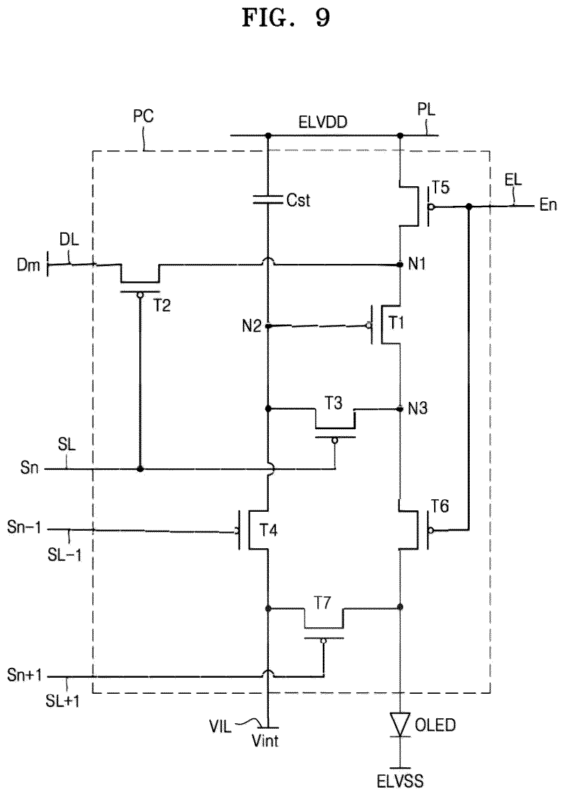

FIG. 9 is an equivalent circuit diagram of the pixel circuit PC electrically connected to the display element, such as the organic light-emitting diode OLED, included in the display panel 10 of FIG. 8.

As illustrated in FIG. 9, the pixel circuit PC including a plurality of thin film transistors and a capacitor may be electrically connected to the display element, such as the organic light emitting diode OLED. FIG. 9, illustrates that the pixel circuit PC includes seven thin film transistors T1 through T7 and a storage capacitor Cst. However, in one or more embodiments, the number and connection relationships thereof may be suitably modified.

The plurality of thin-film transistors T1 to T7 and the storage capacitor Cst may be connected to signal lines SL, SL−1, SL+1, EL, and DL, an initialization voltage line VL, and a driving voltage line PL. At least one of the lines, e.g., the driving voltage line PL, may be shared by neighboring pixels P.

The plurality of thin-film transistors T1 to T7 may include a driving transistor T1, a switching transistor T2, a compensation transistor T3, a first initialization transistor T4, an operation control transistor T5, an emission control transistor T6, and a second initialization transistor T7.

The light-emitting diode LED, such as an OLED, may include a pixel electrode and an opposite electrode, the pixel electrode of the light-emitting diode LED may be to receive supply of a driving current by being connected to the driving transistor T1 via the emission control transistor T6, and the opposite electrode may be to receive supply of a second power voltage ELVSS. The light-emitting diode LED may be to generate light having a luminance corresponding to the driving current.

FIG. 9 illustrates that all of the thin film transistors T1 through T7 are P-channel metal-oxide-semiconductor field-effect transistor (P-channel MOSFETs or PMOSs), but embodiments of the present disclosure are not limited thereto. For example, all of the plurality of thin-film transistors T1 to T7 may be N-channel MOSFETs (NMOSs). In one or more embodiments, one or more of the plurality of thin-film transistors T1 to T7 may be PMOSs, whereas the others may be NMOSs. The plurality of thin-film transistors T1 to T7 may include amorphous (e.g., non-crystalline) silicon and/or polysilicon. In one or more embodiments, at least one or more of the thin-film transistors T1 to T7 may include an oxide semiconductor.

The signal lines may include a scan line SL that transmits a scan signal Sn to the switching transistor T2 and the compensation transistor T3, a previous scan line SL−1 that transmits a previous scan signal Sn'11 to the first initialization transistor T4, a next scan line SL+1 that transmits a next scan signal Sn+1 to the second initialization transistor T7, an emission control line EL that transmits an emission control signal En to the operation control transistor T5 and the emission control transistor T6, and a data line DL that crosses the scan line SL and transmits a data signal Dm.

The driving voltage line PL may be to transmit a driving voltage ELVDD to the driving transistor T1, and the initialization voltage line VL may be to transmit an initialization voltage Vint that initializes the driving transistor T1 and initializes the pixel electrode of the light-emitting diode LED.

A driving gate electrode of the driving transistor T1 may be connected to a first capacitor electrode of the storage capacitor Cst, one selected from among a source region and a drain region of the driving transistor T1 may be connected to the driving voltage line PL via the operation control transistor T5, and the other selected from among the source region and the drain region of the driving transistor T1 may be electrically connected to the pixel electrode of the light-emitting diode LED via the emission control transistor T6. The driving transistor T1 may be to supply the driving current to the light-emitting diode LED by receiving the data signal Dm in response to a switching operation of the switching transistor T2. In one or more embodiments, the driving transistor T1 may be to control an amount of current flowing through the light-emitting diode LED in response to a voltage changed by the data signal Dm.

A switching gate electrode of the switching transistor T2 may be connected to the scan line SL that transmits the scan signal Sn, one selected from among a source region and a drain region of the switching transistor T2 may be connected to the data line DL, and the other selected from among the source region and the drain region of the switching transistor T2 may be connected to the driving transistor T1 and then may be connected to the driving voltage line PL via the operation control transistor T5. The switching transistor T2 may be to transmit the data signal Dm from the data line DL to the driving transistor T1, in response to a voltage applied to the scan line SL. In one or more embodiments, the switching transistor T2 may be turned on in response to the scan signal Sn received through the scan line SL and may be to perform a switching operation of transmitting the data signal Dm, which is transmitted through the data line DL, to the driving transistor T1.

A compensation gate electrode of the compensation transistor T3 may be connected to the scan line SL. One selected from among a source region and a drain region of the compensation transistor T3 may be connected to the pixel electrode of the light-emitting diode LED via the emission control transistor T6. The other selected from among the source region and the drain region of the compensation transistor T3 may be connected to the first capacitor electrode of the storage capacitor Cst and the driving gate electrode of the driving transistor T1. The compensation transistor T3 may be turned on in response to the scan signal Sn received through the scan line SL and may cause the driving transistor T1 to be diode-connected thereto.

A first initialization gate electrode of the first initialization transistor T4 may be connected to the previous scan line SL−1. One selected from among a source region and a drain region of the first initialization transistor T4 may be connected to the initialization voltage line VL. The other selected from among the source region and the drain region of the first initialization transistor T4 may be connected to a lower electrode of the storage capacitor Cst and the driving gate electrode of the driving transistor T1. The first initialization transistor T4 may be turned on in response to the previous scan signal Sn−1 received through the previous scan line SL−1 and may be to perform an initialization operation of initializing a voltage of the driving gate electrode of the driving transistor T1 by transmitting the initialization voltage Vint to the driving gate electrode of the driving transistor T1.

An operation control gate electrode of the operation control transistor T5 may be connected to the emission control line EL, one selected from among a source region and a drain region of the operation control transistor T5 may be connected to the driving voltage line PL, and the other may be connected to the driving transistor T1 and the switching transistor T2.

An emission control gate electrode of the emission control transistor T6 may be connected to the emission control line EL, one selected from among a source region and a drain region of the emission control transistor T6 may be connected to the driving transistor T1 and the compensation transistor T3, and the other selected from among the source region and the drain region of the emission control transistor T6 may be electrically connected to the pixel electrode of the light-emitting diode LED.

The operation control transistor T5 and the emission control transistor T6 may be concurrently (e.g., simultaneously) turned on in response to the emission control signal En received through the emission control line EL and may be to cause the driving voltage ELVDD to be transmitted to the light-emitting diode LED through the driving transistor T1, such that the driving current flows through the light-emitting diode LED.

A second initialization gate electrode of the second initialization transistor T7 may be connected to the next scan line SL+1, one selected from among a source region and a drain region of the second initialization transistor T7 may be connected to the pixel electrode of the light-emitting diode LED, and the other selected from among the source region and the drain region of the second initialization transistor T7 may be connected to the initialization voltage line VL to receive supply of the initialization voltage Vint. The second initialization transistor T7 may be turned on in response to the next scan signal Sn+1 received through the next scan line SL+1 and may be to initialize the pixel electrode of the light-emitting diode LED. For reference, the next scan line SL+1 may be a scan line SL of a pixel that is adjacent to the pixel P as illustrated in FIG. 4 and electrically connected to the data line DL. For example, the scan line SL may be to transmit substantially the same electrical signal with a time difference and function as a scan line SL of one pixel or function as a next scan line SL+1 of an adjacent pixel.

The storage capacitor Cst may include the first capacitor electrode and a second capacitor electrode. The first capacitor electrode of the storage capacitor Cst may be connected to the driving gate electrode of the driving transistor T1, and the second capacitor electrode of the storage capacitor Cst may be connected to the driving voltage line PL. The storage capacitor Cst may be to store an electric charge corresponding to a difference between the voltage of the driving gate electrode of the driving transistor T1 and the driving voltage ELVDD.

More detailed operations of each pixel P according to one or more embodiments are as follows.

During an initialization period, if (e.g., when) the previous scan signal Sn−1 is supplied through the previous scan line SL−1, the first initialization transistor T4 may be turned on, and the driving transistor T1 may be initialized by the initialization voltage Vint supplied from the initialization voltage line VL.

During a data programming period, if (e.g., when) the scan signal Sn is supplied through the scan line SL, the switching transistor T2 and the compensation transistor T3 may be turned on. In this case, the driving transistor T1 may be diode-connected by the compensation transistor T3 that is turned on and biased in a forward direction. Then, a compensation voltage (Dm+Vth, Vth has a negative value) that is obtained by subtracting a threshold voltage (Vth) of the driving transistor T1 from the data signal Dm supplied from the data line DL may be applied to the driving gate electrode of the driving transistor T1. The driving voltage ELVDD and the compensation voltage (Dm+Vth) may be applied to opposite ends of the storage capacitor Cst, and the storage capacitor Cst may store an electric charge corresponding to a difference between voltages at opposite ends thereof.

During an emission period, the operation control transistor T5 and the emission control transistor T6 may be turned on in response to the emission control signal En supplied from the emission control line EL. The driving current may be generated according to the difference between the voltage of the driving gate electrode of the driving transistor T1 and the driving voltage ELVDD, and the driving current may be supplied to the light-emitting diode LED through the emission control transistor T6.

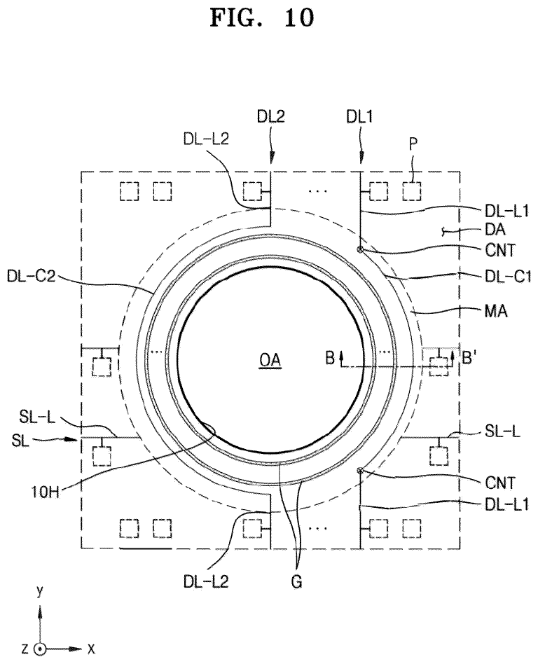

FIG. 10 is a plan view schematically illustrating the opening area OA, the intermediate area MA, and a portion of the display area DA of the display panel 10 of FIG. 8. As illustrated in FIG. 10, pixels P may be arranged in the display area DA.

The intermediate area MA, which may be referred to as the first area, may be between the opening area OA and the display area DA, which may be referred to as the second area. In plan view, pixels P adjacent to the opening area OA may be spaced and/or apart (e.g., spaced apart or separated) from each other with respect to the opening area OA. For example, the pixels P may be spaced and/or apart (e.g., spaced apart or separated) in the vertical direction (y-axis direction) with respect to the opening area OA or may be spaced and/or apart (e.g., spaced apart or separated) from each other in the left and right directions (x-axis direction) with respect to the opening area OA.

Among signal lines that supply signals to pixel circuits connected to light-emitting diodes of respective pixels P, signal lines adjacent to the opening area OA may bypass the opening area OA and/or the through-hole 10H. One or more of data lines DL passing through the display area DA may be in substantially the same column, extend (in the y-axis direction) to provide data signals to pixels P on one side (in a +y direction) of the opening area OA and pixels P on the other side (in the −y direction) of the opening area OA and may bypass the opening area OA and/or the through-hole 10H along edges of the opening area OA and/or through-hole 10H in the intermediate area MA.

FIG. 10 illustrates that a first data line DL1 includes a first extension portion DL-L1 electrically connected to the pixels P on one side (in the +y direction) of the opening area OA, a first extension portion DL-L1 electrically connected to the pixels P on the other side (in the −y direction) of the opening area OA, and a first bypass portion DL-C1 bypassing the opening area OA and/or the through-hole 10H along the edges of the opening area OA and/or the through-hole 10H in the intermediate area MA. The first bypass portion DL-C1 may electrically connect the two first extension portions DL-L1 spaced and/or apart (e.g., spaced apart or separated) from each other. As illustrated in FIG. 1, the first bypass portion DL-C1 may be substantially arranged on one side (in a +x direction) of the opening area OA. The first bypass portion DL-C1 may be on a different layer from a layer on which the first extension portions DL-L1 are arranged, in which case, as illustrated in FIG. 10, the first bypass portion DL-C1 may be connected to the first extension portions DL-L1 through contact holes CNT. In one or more embodiments, the first bypass portion DL-C1 and the first extension portions DL-L1 may also be integrally formed or provided as a single body.

FIG. 10 illustrates that a second data line DL2 includes a second extension portion DL-L2 electrically connected to the pixels P on one side (in the +y direction) of the opening area OA, a second extension portion DL-L2 electrically connected to the pixels P on the other side (in the −y direction) of the opening area OA, and a second bypass portion DL-C2 bypassing the opening area OA and/or the through-hole 10H along the edges of the opening area OA and/or the through-hole 10H in the intermediate area MA. The second bypass portion DL-C2 may electrically connect the two second extension portions DL-L2 spaced and/or apart (e.g., spaced apart or separated) from each other. As illustrated in FIG. 10, the second bypass portion DL-C2 may be substantially arranged on one side (in the −x direction) of the opening area OA. As illustrated in FIG. 10, the second bypass portion DL-C2 and the second extension portions DL-L2 may be integrally formed or provided as a single body. In one or more embodiments, the second bypass portion DL-C2 may be on a different layer from a layer on which the second extension portions DL-L2 are arranged, in which case the second bypass portion DL-C2 may be connected to the second extension portions DL-L2 through contact holes.

The scan line SL may be separated or disconnected with respect to the opening area OA. FIG. 10 illustrates that the scan line SL includes two sub-scan lines SL-L separated with respect to the opening area OA. A sub-scan line SL-L on the left side (in a −x direction) of the opening area OA may be to receive a signal from the scan driver 11 on the left side (in the −x direction) of the display area DA, and a sub-scan line SL-L on the right side (in the +x direction) of the opening area OA may be to receive a signal from the scan driver 12 on the right side (in the +x direction) of the display area DA. In one or more embodiments, these sub-scan lines SL-L may be electrically connected to each other by a bypass portion in the intermediate area MA, and the display panel 10 may include one scan driver.

Grooves G may be in the intermediate area MA. The grooves G may be between the opening area OA and an area where the data lines DL bypass. For example, the grooves G may be between the first bypass portion DL-C1 and the opening area OA and between the second bypass portion DL-C2 and the opening area OA. In plan view viewed from a direction substantially perpendicular to the substrate 100 (z-axis direction), each of the grooves G may have a closed loop shape (e.g., a substantially closed loop shape) around (e.g., surrounding) the opening area OA. The grooves G may be spaced and/or apart (e.g., spaced apart or separated) from each other.

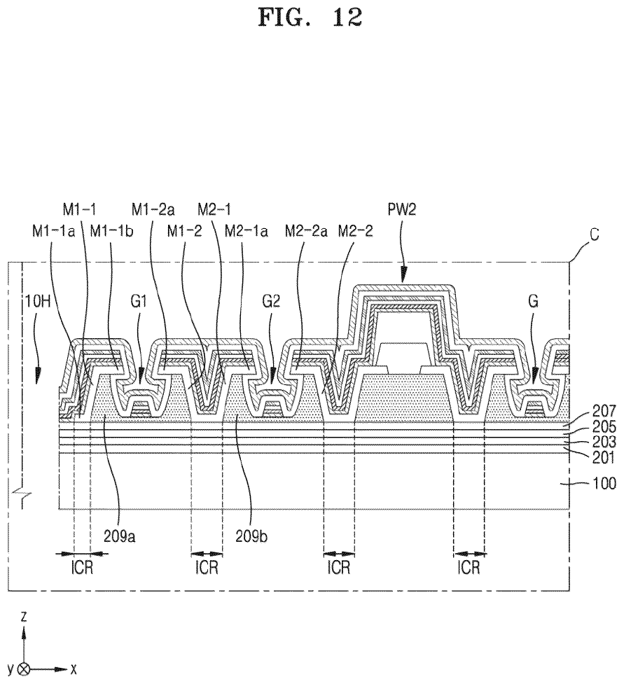

FIG. 11 is a cross-sectional view schematically illustrating a cross-section of the display panel 10 of FIG. 10 taken along the line B-B′, and FIG. 12 is an enlarged cross-sectional view illustrating a portion C of the display panel of FIG. 11.

A buffer layer 201 may be arranged over the substrate 100. The buffer layer 201 may prevent impurities from penetrating (or reduce a degree to or occurrence of which impurities penetrate) into a semiconductor layer Act of the thin film transistor TFT. The buffer layer 201 may include an inorganic insulating (e.g., electrically insulating) material, such as silicon nitride, silicon oxynitride, and/or silicon oxide, and may have a single-layer structure or a multi-layer structure.

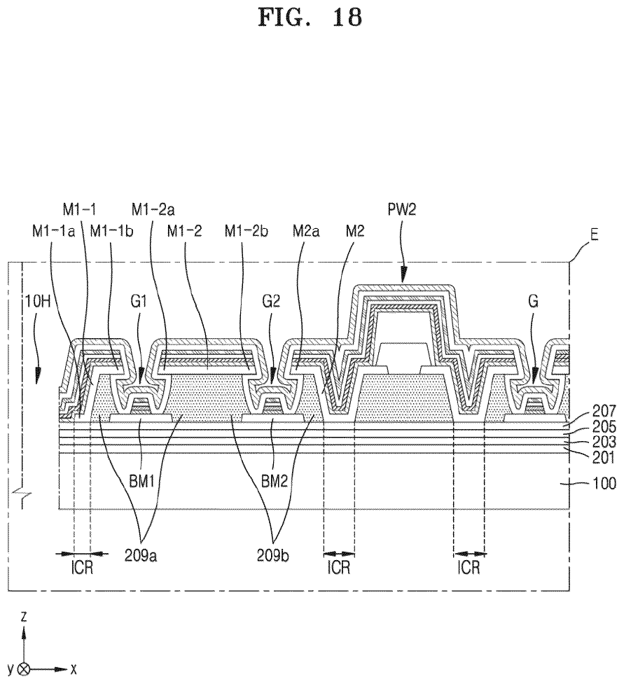

The pixel circuit PC may be arranged on the buffer layer 201. The pixel circuit PC may include the thin film transistor TFT and the storage capacitor Cst. The thin film transistor TFT may include the semiconductor layer Act, a gate electrode GE, a source electrode SE, and/or a drain electrode DE. The thin film transistor TFT as illustrated in FIG. 11 may be the driving transistor. In the pixel circuit PC as described in one or more embodiments with reference to FIG. 9, the emission control transistor T6 may be arranged between the driving transistor T1 and the organic light-emitting diode OLED. In such a case, unlike the structure as illustrated in FIG. 18, the thin film transistor TFT, which is the driving transistor, may not be connected to the pixel electrode 221 of the organic light-emitting diode through the contact metal layer CM, but may be electrically connected to the emission control transistor, and the emission control transistor may be electrically connected to the pixel electrode 221 of the organic light-emitting diode. For convenience of descriptions, a structure in which the thin film transistor TFT of FIG. 11 is connected to the pixel electrode 221 of the organic light-emitting diode through the contact metal layer CM is described herein.

The data line DL of the pixel circuit PC may be electrically connected to the switching transistor included in the pixel circuit PC.

The semiconductor layer Act may include polycrystalline silicon. In one or more embodiments, the semiconductor layer Act may include amorphous (e.g., non-crystalline) silicon, an oxide semiconductor, and/or an organic semiconductor. The gate electrode GE may include a low resistance (e.g., electrical resistance) metal material. For example, the gate electrode GE may include a conductive (e.g., electrically conductive) material including molybdenum (Mo), aluminum (Al), copper (Cu), and/or titanium (Ti) and may have a multi-layer structure or a single-layer structure. For example, the gate electrode GE may have a three-layer structure of a molybdenum layer, an aluminum layer, and a molybdenum layer (Mo/Al/Mo).

The gate insulating layer 203 between the semiconductor layer Act and the gate electrode GE may include an inorganic insulating (e.g., electrically insulating) material, such as silicon oxide, silicon nitride, silicon oxynitride, aluminum oxide, titanium oxide, tantalum oxide, and/or hafnium oxide. The gate insulating layer 203 may have a single-layer structure or a multi-layer structure.

The source electrode SE and the drain electrode DE may be arranged on substantially the same layer as the data line DL and may include substantially the same material as the data line DL. The source electrode SE, the drain electrode DE, and the data line DL may include a material with high conductivity (e.g., electrical conductivity). The source electrode SE and the drain electrode DE may include a conductive (e.g., electrically conductive) material including molybdenum (Mo), aluminum (Al), copper (Cu), titanium (Ti), and/or the like and may have a multi-layer structure or a single-layer structure. For example, the source electrode SE, the drain electrode DE, and the data line DL may have a multi-layer structure of a titanium layer, an aluminum layer, and a titanium layer (Ti/Al/Ti).

FIG. 11 illustrates that the thin film transistor TFT includes both (e.g., simultaneously) the source electrode SE and the drain electrode DE, but embodiments of the present disclosure are not limited thereto. For example, the drain region of the semiconductor layer Act of the thin film transistor TFT may be integrally formed or arranged with a source region of a semiconductor layer of another thin film transistor, and in this case, the thin film transistor TFT may not have the drain electrode DE and the other thin film transistor may not have a source electrode. In this case, the circuit diagram may show the drain of a thin film transistor TFT as being connected to the source of the other thin film transistor. In the pixel circuit PC as illustrated in FIG. 9, the drain of the driving transistor T1 and the source of the emission control transistor T6 are illustrated to be connected. In this case, the driving transistor T1 may not have the drain electrode and the emission control transistor T6 may not have the source electrode, and the drain region of the semiconductor layer of the driving transistor T1 and the source region of the emission control transistor T6 may be integrally formed or provided as a single body. Similarly, in the pixel circuit PC as illustrated in FIG. 9, because the source of the driving transistor T1 is connected to the drain of the operation control transistor T5, the driving transistor T1 may not have the source electrode and the operation control transistor T5 may not have the drain electrode, and the source region of the semiconductor layer of the driving transistor T1 and the drain region of the operation control transistor T5 may be integrally formed or provided as a single body. Accordingly, the driving transistor T1 may not have both (e.g., simultaneously) the source electrode and the drain electrode.

The storage capacitor Cst may include a lower electrode CE1 and an upper electrode CE2 that overlap each other with a first interlayer insulating layer 205 therebetween. The storage capacitor Cst may overlap the thin film transistor TFT. FIG. 11 illustrates that the gate electrode GE of the thin film transistor TFT is the lower electrode CE1 of the storage capacitor Cst. In one or more embodiments, the storage capacitor Cst may not overlap the thin film transistor TFT. A second interlayer insulating layer 207 may cover the storage capacitor Cst. The upper electrode CE2 of the storage capacitor Cst may include a conductive (e.g., electrically conductive) material including molybdenum (Mo), aluminum (Al), copper (Cu), and/or titanium (Ti) and may have a multi-layer structure or a single-layer structure.

The first interlayer insulating layer 205 and the second interlayer insulating layer 207 may include an inorganic insulating (e.g., electrically insulating) material, such as silicon oxide, silicon nitride, silicon oxynitride, aluminum oxide, titanium oxide, tantalum oxide, and/or hafnium oxide. The first interlayer insulating layer 205 and the second interlayer insulating layer 207 may have a single-layer structure or a multi-layer structure.

A first organic insulating layer 209 may cover the pixel circuit PC including the thin film transistor TFT and the storage capacitor Cst.

The pixel circuit PC may be electrically connected to a pixel electrode 221. For example, as illustrated in FIG. 11, the contact metal layer CM may be between the thin film transistor TFT and the pixel electrode 221. The contact metal layer CM may be connected to the thin film transistor TFT through a contact hole defined in the first organic insulating layer 209, and the pixel electrode 221 may be connected to the contact metal layer CM through a contact hole defined in the second organic insulating layer 211 arranged on the first organic insulating layer 209 to cover the contact metal layer CM. The contact metal layer CM may include a conductive (e.g., electrically conductive) material including molybdenum (Mo), aluminum (Al), copper (Cu), and/or titanium (Ti) and may have a multi-layer structure or a single-layer structure. For example, the contact metal layer CM may have a multi-layer structure of a titanium layer, an aluminum layer, and a titanium layer (Ti/Al/Ti).

The first organic insulating layer 209 and the second organic insulating layer 211 may include an organic insulating (e.g., electrically insulating) material, such as acrylic, polystyrene (PS), polymethylmethacrylate (PMMA), benzocyclobutene (BCB), polyimide, and/or hexamethyldisiloxane (HMDSO). For example, the first organic insulating layer 209 and the second organic insulating layer 211 may include polyimide. The first organic insulating layer 209 and/or the second organic insulating layer 211 may have a substantially flat upper surface.

The pixel electrode 221 on the second organic insulating layer 211 may be a (semi)transparent electrode or a reflective electrode. For example, the pixel electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound (e.g., combination or alloy) thereof, and a transparent or semitransparent electrode layer on the reflective layer. The transparent or semitransparent electrode layer may include at least one selected from the group consisting of indium tin oxide (ITO), indium zinc oxide (IZO), zinc oxide (ZnOₓ, wherein 0<x≤2; e.g., ZnO or ZnO₂), indium oxide (e.g., In₂O₃), indium gallium oxide (IGO), and aluminum zinc oxide (AZO). For example, the pixel electrode 221 may have a three-layer structure of ITO/Ag/ITO.

A pixel definition layer 215 may be arranged over the second organic insulating layer 211. The pixel definition layer 215 may prevent arcs and/or the like from occurring (or reduce a degree to or occurrence of which arcs and/or the like occur) at the edge of the pixel electrode 221 by covering the edge of the pixel electrode 221 and increasing the distance between the pixel electrode 221 and the common electrode 223 above the pixel electrode 221. For example, the pixel definition layer 215 may have an opening to expose the central portion of the pixel electrode 221. The pixel definition layer 215 may be formed or arranged by a method, such as spin coating, and may include one or more organic insulating (e.g., electrically insulating) materials selected from the group consisting of polyimide, polyamide, an acrylic resin, benzocyclobutene, and a phenolic resin. In one or more embodiments, the pixel definition layer 215 may include an inorganic insulating (e.g., electrically insulating) material, such as silicon nitride (e.g., SiNₓ, wherein 0<x≤2; e.g., Si₃N₄), silicon oxynitride (e.g., SiOₓN_{y}, wherein 0<x≤2 and 0≤y≤2; e.g., SiON or Si₂N₂O), and/or silicon oxide (e.g., SiO_{X}, wherein 0<x≤2; e.g., SiO₂).

An intermediate layer 222 between the pixel electrode 221 and the common electrode 223 may include an emission layer 222b. The intermediate layer 222 may include a first functional layer 222a between the emission layer 222b and the pixel electrode 221 or may include a second functional layer 222c between the emission layer 222b and the common electrode 223. The emission layer 222b may be to emit light of a set or predetermined color and may include a polymer (e.g., a high molecular weight organic material) and/or a low molecular weight organic material.

The first functional layer 222a may include a single layer or a multi-layer. For example, if (e.g., when) the first functional layer 222a includes a polymer material, the first functional layer 222a may have a single-layer structure including a hole transport layer (HTL) and may include polyethylene dihydroxythiophene (PEDOT: poly-(3,4)-ethylene-dihydroxy thiophene) and/or polyaniline (PANI: polyaniline). If (e.g., when) the first functional layer 222a includes a low-molecular-weight material, the first functional layer 222a may include a hole injection layer (HIL) and the hole transport layer (HTL).

The second functional layer 222c may include an electron transport layer (ETL) and/or an electron injection layer (EIL).

In one or more embodiments, unlike the structure as illustrated in FIG. 11, the intermediate layer 222 may include a first stack including an emission layer 222b and a functional layer, a second stack including an emission layer 222b and a functional layer, and a charge generation layer between the first stack and the second stack. The charge generation layer may include a negative charge generation layer and a positive charge generation layer. The emission efficiency of a tandem light-emitting diode LED having a plurality of emission layers may be further increased or enhanced by the negative charge generation layer and the positive charge generation layer.

The negative charge generation layer may be a negative type (kind) charge generation layer (or an n-type (kind) charge generation layer). The negative charge generation layer may be to supply electrons. The negative charge generation layer may include a host and a dopant. The host may include an organic material. The dopant may include a metal material. The positive charge generation layer may be a positive type (kind) charge generation layer (or a p-type (kind) charge generation layer). The positive charge generation layer may be to supply holes. The positive charge generation layer may include a host and a dopant. The host may include an organic material. The dopant may include a metal material.

The emission layer 222b may have a patterned shape corresponding to the pixel electrode 221. Layers included in the intermediate layer 222 other than the emission layer 222b may be formed or arranged in one or more suitable ways. For example, a layer included in the intermediate layer 222 other than the emission layer 222b may be integrally formed or provided as a single body throughout the plurality of pixel electrodes 221. Layers included in the intermediate layer 222 other than the emission layer 222b may also be in the intermediate area MA.

The common electrode 223 may be a light-transmitting electrode or a reflective electrode. For example, the common electrode 223 may be a transparent or semitransparent electrode and may include a metal film with a small work function including lithium (Li), calcium (Ca), aluminum (Al), silver (Ag), magnesium (Mg), or a compound thereof (e.g., LiF). In one or more embodiments, the common electrode 223 may further include a transparent (e.g., substantially transparent) conductive (e.g., electrically conductive) oxide film (a TCO film), such as ITO, IZO, ZnO, ZnO₂, and/or In₂O₃ arranged on the metal thin film.

The common electrode 223 may be formed or provided as a single body over the entire (e.g., substantially entire) display area DA to cover the display area DA and may be arranged over the intermediate layer 222 and the pixel definition layer 215. For example, each of the pixel electrodes 221 may be arranged to correspond to each light-emitting diode LED, and the common electrode 223 may be integrally formed or provided as a single body to correspond to the plurality of organic light-emitting diodes OLEDs. The plurality of organic light-emitting diodes OLEDs may share the common electrode 223, and a laminated structure of the pixel electrode 221, the intermediate layer 222, and the common electrode 223 may correspond to the organic light-emitting diode OLED.

The capping layer 230 may be arranged over the common electrode 223. For example, the capping layer 230 may include LiF. In one or more embodiments, the capping layer 230 may not be provided.

A spacer 217 may be arranged on the pixel definition layer 215. The spacer 217 may include an organic insulating (e.g., electrically insulating) material, such as polyimide. In one or more embodiments, the spacer 217 may include an inorganic insulating (e.g., electrically insulating) material or include an organic insulating (e.g., electrically insulating) material and an inorganic insulating (e.g., electrically insulating) material.

The spacer 217 may include a material different from a material of the pixel definition layer 215 or include substantially the same material as a material of the pixel definition layer 215. For example, the pixel definition layer 215 and the spacer 217 may include polyimide. If (e.g., when) the pixel definition layer 215 and the spacer 217 include substantially the same material, the pixel definition layer 215 and the spacer 217 may be formed or arranged concurrently (e.g., simultaneously) in one mask process using a halftone mask. Among the intermediate layers 222 as described in one or more embodiments, the functional layers or the common electrodes 223 may cover the spacer 217.

A thin film encapsulation layer 300 may cover the organic light-emitting diode OLED. The thin film encapsulation layer 300 may include at least one organic encapsulation layer and at least one inorganic encapsulation layer, and FIG. 11 illustrates that the thin film encapsulation layer 300 includes a first inorganic encapsulation layer 310, a second inorganic encapsulation layer 330, and an organic encapsulation layer 320 therebetween. In one or more embodiments, the number of organic and inorganic encapsulating layers and the stacking order may be changed.

Each of the first inorganic encapsulation layer 310 and the second inorganic encapsulation layer 330 may include one or more inorganic materials selected from among aluminum oxide, titanium oxide, tantalum oxide, hafnium oxide, zinc oxide, silicon oxide, silicon nitride, and silicon oxynitride. Each of the first inorganic encapsulation layer 310 and the second inorganic encapsulation layer 330 may have a single-layer structure or a multi-layer structure. The organic encapsulation layer 320 may include a polymer-based material. The polymer material may include acrylic resins, such as polymethyl methacrylate and/or polyacrylic acid, epoxy resins, polyimides, and/or polyethylene. For example, the organic encapsulation layer 320 may include acrylate.

The first inorganic encapsulation layer 310 and the second inorganic encapsulation layer 330 may include different materials. For example, the first inorganic encapsulation layer 310 may include silicon oxynitride, and the second inorganic encapsulation layer 330 may include silicon nitride.

The intermediate area MA as illustrated in FIG. 11 may include a first sub-intermediate area SMA1 and a second sub-intermediate area SMA2. The first sub-intermediate area SMA1 may be relatively farther from the opening area OA where the through hole 10H of the display panel 10, e.g., the first hole H1 of the substrate 100, exists than the second sub-intermediate area SMA2. For example, the second sub-intermediate area SMA2 may be closer to the opening area OA than the first sub-intermediate area SMA1. The lines and grooves G1, G2, and G that bypass the opening area OA may be arranged in the intermediate area MA.

Lines, such as data lines DL, may be arranged in the first sub-intermediate area SMA1. The data lines DL in the first sub-intermediate area SMA1 as illustrated in FIG. 11 may correspond to the bypass portions of the data lines DL as described in one or more embodiments with reference to FIG. 10, such as the first bypass portion DL-C1 and/or the second bypass portion DL-C2. The first sub-intermediate area SMA1 may be a line area or a bypass area through which lines, such as data lines DLs, bypass.

In the first sub-intermediate area SMA1, data lines DL may be arranged alternately with an insulating (e.g., electrically insulating) layer between them. For example, one of the neighboring data lines DL may be arranged below the insulating layer (e.g., the first organic insulating layer, 209) and the other may be arranged on the insulating layer (e.g., the first organic insulating layer, 209). If (e.g., when) data lines DL are arranged alternately with an insulating (e.g., electrically insulating) layer between them, the distance (Δd, pitch) between neighboring data lines in plan view may be reduced. FIG. 11 illustrates data lines DL in the first sub-intermediate area SMA1. However, in one or more embodiments, bypass portions of the scan lines SL may also be in the first sub-intermediate area SMA1.

In the second sub-intermediate area SMA2, grooves G1, G2, and G may be arranged. The organic layer included in the intermediate layer 222, such as the first functional layer 222a and/or the second functional layer 222c, may be disconnected (or separated) by grooves G1, G2, and/or G. The second sub-intermediate area SMA2 may be referred to as a groove area or a disconnection area (or separation area) of the organic layer.

The grooves G1, G2, and G may be formed or arranged by a layer between the substrate 100 and the organic light-emitting diode OLED which is the display element. FIG. 11 illustrates that the first organic insulating layer 209, which may be referred to as an upper layer and is arranged over the second interlayer insulating layer 207 which may be referred to as a lower layer, has the grooves G1, G2, and G. If (e.g., when) necessary or desired, each of the grooves G1, G2, and G may be formed or arranged through multiple layers.

Among the grooves G1, G2, and G in the intermediate area MA which may be referred to as the first area, the first groove G1, which is a groove closest to the opening area OA where the through-hole of the substrate 100 is arranged, may be formed or arranged (or defined) in the first upper layer 209a arranged over the second interlayer insulating layer 207, which may be referred to as the lower layer. The first upper layer 209a may be a part of the first organic insulating layer 209. In one or more embodiments, the first upper layer 209a may be formed or arranged concurrently (e.g., simultaneously) with the first organic insulating layer 209 using substantially the same material during the manufacturing process such that the first upper layer 209a is apart from the first organic insulating layer 209. The first groove G1 may extend along at least a portion of the opening area OA or may encircle (e.g., may be around or may surround) the opening area OA as described in one or more embodiments with reference to FIG. 10. Materials to form the intermediate layer 222, the common electrode 223, and the capping layer 230 may be within the first groove G1. This may also apply to other grooves as described herein.

A first-1 metal layer M1-1 may be arranged over the second interlayer insulating layer 207, which may be referred to as the lower layer, and the first upper layer 209a. The first metal layer M1-1 may be formed or arranged concurrently (e.g., simultaneously) with the contact metal layer CM using substantially the same material during the manufacturing process. The first-1 metal layer M1-1 may be in the direction to the opening area OA where the through-hole 10H is arranged (in −x direction), with respect to the center of the first groove G1 of the first upper layer 209a. An end M1-1a of the first-1 metal layer M1-1 in the direction to the opening area OA (in −x direction) may be arranged on the second interlayer insulating layer 207, which may be referred to as the lower layer, and an end M1-1b of the first-1 metal layer M1-1 in the direction to the center of the first groove G1 may protrude from the first upper layer 209a and be within the first groove G1.

In one or more embodiments, the first-2 metal layer M1-2, which is apart from the first-1 metal layer M1-1, may be arranged over the first upper layer 209a and the second interlayer insulating layer 207, which may be referred to as the lower layer, so as to be in the direction (e.g., such that the first-2 metal layer M1-2 is in the direction) to the display area DA which is the second area (in +x direction), with respect to the center of the first groove G1. An end M1-2a of the first-2 metal layer M1-2 in the direction to the center of the first groove G1 may protrude from the first upper layer 209a and be within the first groove G1.

In this way, the end M1-1b of the first-1 metal layer M1-1 in the direction to the center of the first groove G1 may protrude from the first upper layer 209a and may be within the first groove G1, and the end M1-2a of the first-2 metal layer M1-2 in the direction to the center of the first groove G1 may protrude from the first upper layer 209a and may be within the first groove G1. Therefore, if (e.g., when) considering a set of the first upper layer 209a, the first-1 metal layer M1-1, and the first-2 metal layer M1-2, the first groove G1 may be understood to have an undercut structure. The end M1-1b of the first-1 metal layer M1-1 protruding from the first upper layer 209a may be referred to as a protruding tip, and a length of the protruding tip protruding from the first upper layer 209a may be about 0.3 μm to about 0.5 μm. For example, the length of the protruding tip of the first-1 metal layer M1-1 protruding from the first upper layer 209a may be about 0.4 μm. A length of the end M1-2a of the first-2 metal layer M1-2 protruding from the first upper layer 209a may also be about 0.3 μm to about 0.5 μm. For example, the length of the protruding tip of the first-2 metal layer M1-2 protruding from the first upper layer 209a may be about 0.4 μm.

As described in one or more embodiments, the functional layer included in the intermediate layer 222 may be formed or arranged to approximately or substantially correspond to the entire (e.g., substantially entire) surface of the substrate 100, and then a portion of the substrate 100 and/or the like may be removed to form (or define) the through-hole 10H in the display panel 10. Accordingly, at least a portion of the functional layer may be exposed to the outside at the inner side surface of the through-hole 10H, and moisture and/or the like from the outside may penetrate into the functional layer through the exposed portion of the functional layer, may move through the functional layer to the display area DA, and may cause a defect in the display panel 10. However, in the case of the display panel 10 according to one or more embodiments and the electronic apparatus 1 having substantially the same, as described in one or more embodiments, the first groove G1 having the undercut structure may be formed or arranged before forming or arranging the intermediate layer 222 during the manufacturing process. Accordingly, the functional layer included in the intermediate layer 222 may be disconnected by the first groove G1 of the undercut structure as illustrated in FIG. 12. Therefore, even if (e.g., when) moisture penetrates into the functional layer exposed to the outside at the inner side surface of the through-hole 10H, the moving of the moisture toward the display area DA may be effectively or suitably prevented or minimized or reduced.

As described in one or more embodiments, in the case of the first-1 metal layer M1-1 in the direction to the opening area OA (in −x direction) with respect to the center of the first groove G1, which is the groove closest to the opening area OA, the end M1-1a of the first-1 metal layer in the direction to the opening area OA (in −x direction) may be arranged on the second interlayer insulating layer 207, which may be referred to as the lower layer. The bonding force between the first metal layer M1-1 including metal and the inorganic insulating layer may be stronger than the bonding force between the first metal layer M1-1 including metal and the organic insulating layer. As described in one or more embodiments, because the second interlayer insulating layer 207 includes an inorganic insulating (e.g., electrically insulating) material, the end M1-1a of the first-1 metal layer M1-1 in the direction to the opening area OA (in −x direction) may be strongly bonded to the second interlayer insulating layer 207. This may prevent or minimize or reduce defects (e.g., a degree or occurrence of defects), such as delamination between layers near the opening area OA.

The second groove G2, which is the second closest to the opening area OA where the through-hole of the substrate 100 is arranged, among the grooves G1, G2, and G in the intermediate area MA which may be referred to as the first area, may be formed or arranged (or defined) in the second upper layer 209b arranged over the second interlayer insulating layer 207 which may be referred to as the lower layer. The second upper layer 209b may be a part of the first organic insulating layer 209. In one or more embodiments, the second upper layer 209b may be formed or arranged concurrently (e.g., simultaneously) with the first organic insulating layer 209 using substantially the same material during the manufacturing process such that the second upper layer 209b is apart from the first organic insulating layer 209 to be arranged between the display area DA and the first upper layer 209a. The second upper layer 209b may be apart (or separated) from the first upper layer 209a. The second groove G2 may extend along at least a portion of the opening area OA or may encircle (e.g., may be around or may surround) the opening area OA as described in one or more embodiments with reference to FIG. 10.

A second-1 metal layer M2-1 may be arranged over the second upper layer 209b and the second interlayer insulating layer 207 which may be referred to as the lower layer. The second-1 metal layer M2-1 may be formed or arranged concurrently (e.g., simultaneously) with the contact metal layer CM using substantially the same material during the manufacturing process. The second-1 metal layer M2-1 may be in the direction to the opening area OA where the through-hole 10H is arranged (in −x direction), with respect to the center of the second groove G2 defined in the second upper layer 209b. An end M2-1a of the second-1 metal layer M2-1 in the direction to the center of the second groove G2 may protrude from the second upper layer 209b and be arranged within the second groove G2.

A second-2 metal layer M2-2 which is apart from the second-1 metal layer M2-1 may be arranged over the second upper layer 209b and the second interlayer insulating layer 207 which may be referred to as the lower layer, such that the second-2 metal layer M2-2 is in the direction to the display area DA which is the second area (in +x direction), with respect to the center of the second groove G2. An end M2-2a of the second-2 metal layer M2-2 in the direction to the center of the second groove G2 may protrude from the second upper layer 209b and be within the second groove G2.

In this way, the end M2-1b of the second-1 metal layer M2-1 in the direction to the center of the second groove G2 may protrude from the second upper layer 209b and may be within the second groove G2, and the end M2-2a of the second-2 metal layer M2-2 in the direction to the center of the second groove G2 may protrude from the second upper layer 209b and may be within the second groove G2. Therefore, if (e.g., when) considering a set of the second upper layer 209b, the second-1 metal layer M2-1, and the second-2 metal layer M2-2, the second groove G2 may be understood to have an undercut structure. The end M2-1b of the second-1 metal layer M2-1 protruding from the second upper layer 209b may be referred to as a protruding tip, and a length of the protruding tip protruding from the second upper layer 209b may be about 0.3 μm to about 0.5 μm. For example, the length of the protruding tip of the second-1 metal layer M2-1 protruding from the second upper layer 209b may be about 0.4 μm. A length of the end M2-2a of the second-2 metal layer M2-2 protruding from the second upper layer 209b may also be about 0.3 μm to about 0.5 μm. For example, the length of the protruding tip of the second-2 metal layer M2-2 protruding from the second upper layer 209b may be about 0.4 μm.

As described in one or more embodiments, the functional layer included in the intermediate layer 222 may be disconnected by the first groove G1 of the undercut structure as described in one or more embodiments and may also be disconnected by the second groove G2 of the undercut structure. Accordingly, even if (e.g., when) moisture penetrates into the functional layer exposed to the outside at the inner side surface of the through-hole 10H, the moving of the moisture toward the display area DA may be effectively or suitably prevented or minimized or reduced.

As illustrated in FIGS. 11 and 12, the first-2 metal layer M1-2 and the second-1 metal layer M2-1 may be integrally formed or provided as a single body. Therefore, the first-2 metal layer M1-2 and the second-1 metal layer M2-1 which are integrally formed or provided as a single body may contact the second interlayer insulating layer 207, which may be referred to as the lower layer, between the first upper layer 209a and the second upper layer 209b. The metal layer and the second interlayer insulating layer 207 which are in contact with each other between the first upper layer 209a and the second upper layer 209b may form an inorganic contact region (ICR) with strong bonding force. As described in one or more embodiments, the end M1-1a of the first-1 metal layer M1-1 in the direction to the opening area OA (in −x direction) may also come into contact with the second interlayer insulating layer 207 to form an inorganic contact area ICR with strong bonding strength.

Similar to the functional layers, the common electrode 223 may also be disconnected in the first groove G1 and the second groove G2. The capping layer 230 including LiF and/or the like may also be disconnected in the first groove G1 and the second groove G2. If (e.g., when) the capping layer 230 includes an inorganic material, such as silicon nitride, silicon oxide, and/or silicon oxynitride, the capping layer 230 may be formed or arranged continuously without being disconnected by the first groove G1 and the second groove G2. For convenience, a case where the capping layer 230 is disconnected by the first groove G1 and the second groove G2 will be described herein in more detail.

A first partitioning wall PW1 and a second partitioning wall PW2 may be in the intermediate area MA. Although FIG. 11 illustrates that the first partitioning wall PW1 and the second partitioning wall PW2 are in the intermediate area MA, embodiments of the present disclosure are not limited thereto. For example, three partitioning walls may be in the intermediate area MA. The first partitioning wall PW1 may be closer to the display area DA than the second partitioning wall PW2. Each of the first partitioning wall PW1 and the second partitioning wall PW2 may have a shape which is around (e.g., surrounds) the opening area OA in plan view.

Each of the first partitioning wall PW1 and the second partitioning wall PW2 may include a plurality of sequentially stacked organic insulating (e.g., electrically insulating) layers. For example, the first partitioning wall PW1 may have a structure in which a part 209P of the first organic insulating layer 209, a part 211P of the second organic insulating layer 211, a part 215P of the pixel definition layer 215, and a part 217P of the spacer 217 are sequentially stacked. A part 209P of the first organic insulating layer 209 may be connected to the first organic insulating layer 209 or may be separated from the first organic insulating layer 209. The second partitioning wall PW2 may have a structure in which a part of the first organic insulating layer 209, a part of the second organic insulating layer 211, and a part of the pixel definition layer 215 are sequentially stacked.

A part of each of the functional layers or the common electrode 223 may also be arranged on the first partitioning wall PW1 and the second partitioning wall PW2, as illustrated in FIG. 11.

The thin film encapsulation layer 300 which may prevent an organic light-emitting diode OLED from being damaged or deteriorated by external impurities (or reduce a degree to or occurrence of which an organic light-emitting diode OLED is damaged or deteriorated by external impurities) may include at least one organic encapsulation layer and at least one inorganic encapsulation layer as described in one or more embodiments.

The first inorganic encapsulation layer 310 formed or arranged by chemical vapor deposition and/or the like may have relatively superior step coverage than the functional layer and/or common electrode 223. Accordingly, as illustrated in FIGS. 11 and 12, the first inorganic encapsulation layer 310 may not be disconnected by the first groove G1 and the second groove G2 and may cover inner side surfaces of the first groove G1 and the second groove G2.

The organic encapsulation layer 320 may be formed or arranged by applying a monomer over the substrate 100 and curing it. In one or more embodiments, the organic encapsulation layer 320 may be formed or arranged by coating a polymer. The first partitioning wall PW1 and/or the second partitioning wall PW2 may prevent the monomer and/or the polymer from flowing (or reduce a degree to or occurrence of which the monomer and/or the polymer flow) in the direction to the opening area OA if (e.g., when) the monomer or polymer is applied on the substrate 100. FIG. 11 illustrates that the area of the organic encapsulation layer 320 is limited by the first partitioning wall PW1. If (e.g., when) the first partitioning wall PW1 and the second partitioning wall PW2 do not exist and the material to form the organic encapsulation layer 320 is applied to the entire (e.g., substantially entire) surface of the substrate 100, then, if (e.g., when) the through-hole 10H is formed or arranged in the display panel 10 later, the organic encapsulation layer 320 may be exposed at the inner side surface of the through-hole 10H. In this case, the organic encapsulation layer 320 may become a path for moisture and/or the like from the outside to penetrate through the inner side surface of the through-hole 10H, which may cause a defect in which the organic light-emitting diode OLED in the display area DA is damaged. However, in the case of the display panel 10 according to one or more embodiments and the electronic apparatus 1 having substantially the same display panel 10, because the first partition wall PW1 and the second partition wall PW2 exist, the occurrence of such defects may be effectively or suitably prevented or minimized or reduced. For reference, even if (e.g., when) the material to form the organic encapsulation layer 320 is excessively (or substantially) applied during the process of forming or arranging the organic encapsulation layer 320 and the material flows to the outside of the first partitioning wall PW1, the second partitioning wall PW2 may prevent the material from flowing (or reduce a degree to or occurrence of which the material flows) further toward the opening area OA.

The second inorganic encapsulation layer 330 may be on the organic encapsulation layer 320. The second inorganic encapsulation layer 330 may directly contact the first inorganic encapsulation layer 310 in a partial region of the intermediate area MA. For example, as illustrated in FIGS. 11 and 12, the first inorganic encapsulation layer 310 and the second inorganic encapsulation layer 330 may be in contact with each other in an area adjacent to the opening area OA in the intermediate area MA.

The first groove G1 and the second groove G2 may be between the second partitioning wall PW2 and the opening area OA. As illustrated in FIG. 11, grooves G each of which has substantially the same or similar shape as the second groove G2 may be between the first partitioning wall PW1 and the second partitioning wall PW2, and grooves G each of which has substantially the same or similar shape as the second groove G2 may be between the first partitioning wall PW1 and the second area, e.g., the display area DA. In the grooves G, metal layers 210 having a shape similar to a structure in which the first-2 metal layer M1-2 and the second-1 metal layer M2-1 are integrally formed or provided as a single body and arranged on the first organic insulating layer 209 exist so that (e.g., such that) tips protruding into the grooves G may be formed or arranged.

FIG. 11 illustrates that two grooves G are between the display area DA and the first partition wall PW1, two grooves G are between the first partition wall PW1 and the second partition wall PW2, and two grooves G1 and G2 are between the second partition wall PW2 and the opening area OA, but embodiments of the present disclosure are not limited thereto. For example, four grooves may be between the display area DA and the first partition wall PW1, four grooves may be between the first partition wall PW1 and the second partition wall PW2, and four grooves may be between the second partition wall PW2 and the opening area OA, such that the total number of the grooves is 12.

As described in one or more embodiments, the protruding length of the tip, which is a portion of the metal layer protruding into the groove, may be about 0.3 μm to about 0.5 μm. For example, the protruding length may be about 0.4 μm. By increasing the number of grooves, the cutting effect (separation effect or disconnecting effect) may be dramatically or substantially improved or enhanced even if (e.g., when) the protruding length of the tip is short. For example, a structure having 12 grooves where the protruding length of the tip of the metal layer is about 0.4 μm may have an effect equivalent to or similar to a structure having 6 grooves where the protruding length of the tip of the metal layer is about 0.8 μm. However, the longer the protruding length of the tip of the metal layer is, the higher the rate of delamination between the metal layer and the upper layer during the manufacturing process may be. In one or more embodiments, because the bonding strength between the metal layer containing inorganic material and the upper layer containing organic material is not large, the possibility of such delamination occurrence may increase rapidly as the protruding length of the tip increases. Such delamination may cause defects during manufacturing. In the case of the display panel 10 according to one or more embodiments and the electronic apparatus 1 having substantially the same display panel 10, the defect occurrence may be drastically or substantially reduced by increasing the number of grooves and reducing the protruding length of each of tips of the metal layer.

The cross-sectional view of the display panel 10 as illustrated in FIGS. 11 and 12 may be understood as a structure around (e.g., surrounding) the first area OA. For example, as described in one or more embodiments, each of the grooves G1, G2, and G of FIG. 11 may have a ring shape (e.g., a substantially ring shape) around (e.g., surrounding) the opening area OA if (e.g., when) viewed in a direction perpendicular (e.g., substantially perpendicular) to the upper surface of the substrate 100, e.g., in plan view, as illustrated in FIG. 10. Similarly, each of the first partitioning wall PW1 and the second partitioning wall PW2 may also have a ring shape (e.g., a substantially ring shape) around (e.g., surrounding) the opening area OA if (e.g., when) viewed in the direction perpendicular (e.g., substantially perpendicular) to the upper surface of the substrate 100. Similarly, each of the first-1 metal layer M1-1 and/or the first-2 metal layer M1-2 may also have a ring shape (e.g., a substantially ring shape) around (e.g., surrounding) the opening area OA if (e.g., when) viewed in the direction perpendicular (e.g., substantially perpendicular) to the upper surface of the substrate 100. This may also be applied to one or more embodiments as described herein.

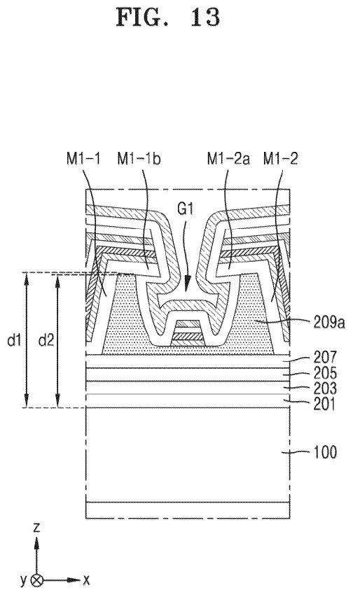

FIG. 13 is a cross-sectional view schematically illustrating a part of the display panel 10 according to one or more embodiments, e.g., the vicinity of the first groove G1. As illustrated in FIG. 13, an upper surface of the first upper layer 209a may have a shape that is inclined with respect to the upper surface of the substrate 100. For example, a distance from the upper surface of the substrate 100 to the upper surface of the first upper layer 209a may decrease as measured moving from a part farther from the center of the first groove G1 to the center of the first groove G1. In one or more embodiments, the distance from the upper surface of the substrate 100 to the upper surface of the first upper layer 209a at an end of the first upper layer 209a in the direction to the center of the first groove G1 may be less than the distance from the upper surface of the substrate 100 to the upper surface of the first upper layer 209a at an end of the first upper layer 209a in a direction away from the first groove G1. As the upper surface of the first upper layer 209a has such a shape, a portion of the first-1 metal layer M1-1 on the upper surface of the first upper layer 209a and the end M1-1b within the first groove G1 may have a shape that is inclined toward the inside of the first groove G1. Similarly, a portion of the first-2 metal layer M1-2 on the upper surface of the first upper layer 209a and the end M1-2a within the first groove G1 may have a shape that is inclined toward the inside of the first groove G1.

Because the first-1 metal layer M1-1 and the first-2 metal layer M1-2 have such a shape, even if (e.g., when) the bonding force between the first-1 metal layer M1-1 and the first upper layer 209a and the bonding force between the first-2 metal layer M1-2 and the first upper layer 209a are low, the possibility of delamination of the first-1 metal layer M1-1 and the first-2 metal layer M1-2 from the first upper layer 209a may be further reduced, thereby reducing the defect occurrence. This structure may be applied to grooves G between the display area DA and the first partitioning wall PW1 or to grooves G between the first partitioning wall PW1 and the second partitioning wall PW2. In one or more embodiments, by applying this structure to the grooves G between the display area DA and the first partitioning wall PW1, it may be feasible to effectively or suitably prevent the metal layer 210 and/or the like from being delaminated (or reduce a degree to or occurrence of which the metal layer 210 and/or the like is delaminated) during the process of applying the material to form the organic encapsulation layer 320. For example, the structural design of the metal layers and the first upper layer around the grooves—for example, their inclined shapes—enhances mechanical stability by reducing the likelihood of delamination. Even if (e.g., when) the bonding strength between the metal layers and the insulating layer is relatively low, the angled configuration or arrangement helps anchor the metal layers more securely within the grooves. This is beneficial during the application of the organic encapsulation layer, where mechanical stress could otherwise cause separation. By applying this design to grooves near the display area and partitioning walls, the display panel achieves improved or enhanced durability and reduced defect rates during manufacturing.

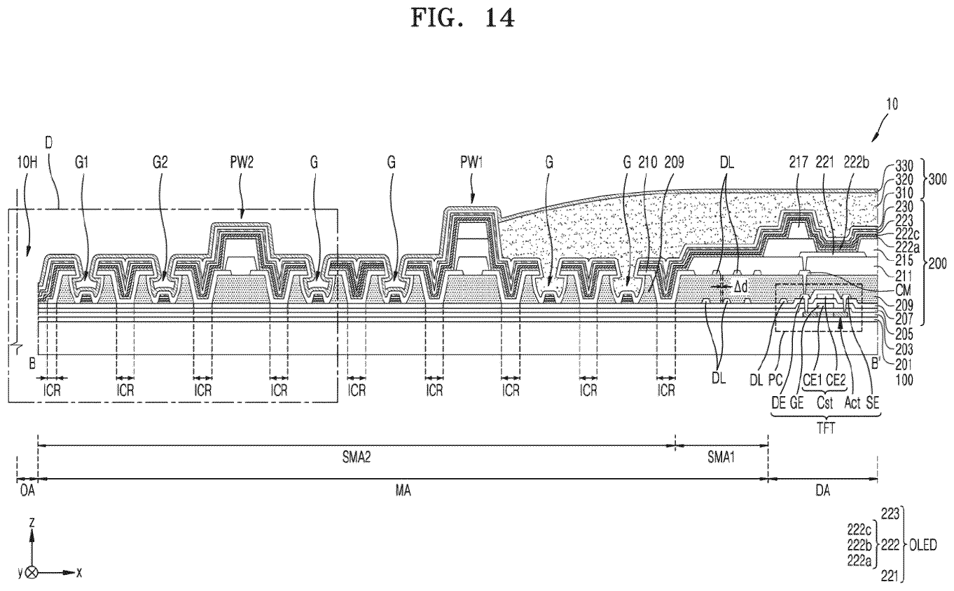

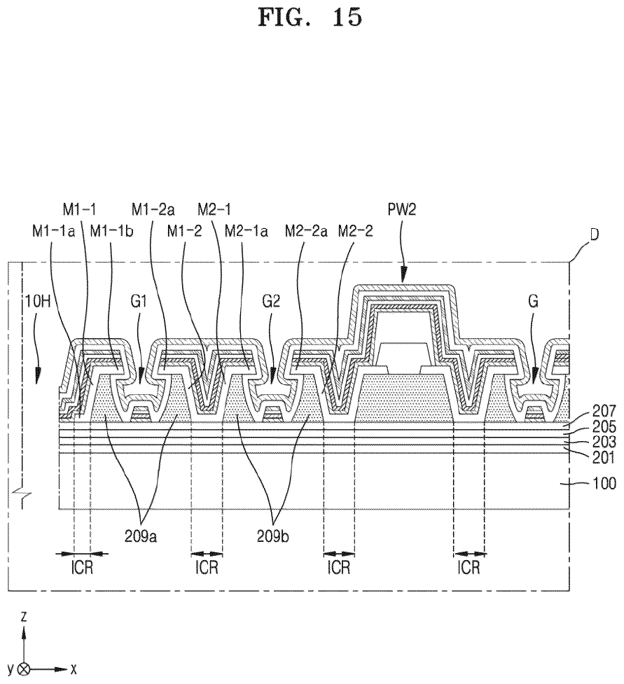

FIG. 14 is a cross-sectional view schematically illustrating a portion of a display panel 10 according to one or more embodiments, and FIG. 15 is an enlarged cross-sectional view illustrating a portion D of the display panel 10 of FIG. 14. In the case of the display panel 10 and the electronic apparatus 1 having substantially the same display panel 10 according to one or more embodiments with reference to FIGS. 11 and 12, the first upper layer 209a, the second upper layer 209b, and/or the like may have grooves. In the case of the display panel 10 and the electronic apparatus 1 having substantially the same display panel 10 according to one or more embodiments, the first upper layer 209a, the second upper layer 209b, and/or the like may have openings.

For example, the first upper layer 209a may be arranged over the second interlayer insulating layer 207 which is the lower layer and may have a first opening exposing the second interlayer insulating layer 207. Materials to form the intermediate layer 222, the common electrode 223, and the capping layer 230 may be arranged on a portion of the second interlayer insulating layer 207 exposed by the first opening, and the first inorganic encapsulation layer 310, the second inorganic encapsulation layer 330, and/or the like may be arranged over the portion of the second interlayer insulating layer 207 exposed by the first opening. This may be also applied to other openings which will be described herein in more detail.

The first-1 metal layer M1-1 may be arranged over the second interlayer insulating layer 207, which may be referred to as the lower layer, and the first upper layer 209a. The first metal layer M1-1 may be formed or arranged concurrently (e.g., simultaneously) with the contact metal layer CM using substantially the same material during the manufacturing process. The first-1 metal layer M1-1 may be in the direction to the opening area OA where the through-hole 10H is arranged (in −x direction), with respect to the center of the first opening of the first upper layer 209a. The end M1-1a of the first-1 metal layer M1-1 in the direction to the opening area OA (in −x direction) may be arranged on the second interlayer insulating layer 207, which may be referred to as the lower layer, and the end M1-1b of the first-1 metal layer M1-1 in the direction to the center of the first opening may protrude from the first upper layer 209a and be within the first opening.

In one or more embodiments, the first-2 metal layer M1-2, which is apart from the first-1 metal layer M1-1, may be arranged over the first upper layer 209a and the second interlayer insulating layer 207, which may be referred to as the lower layer, so as to be in the direction (e.g., such that the first-2 metal layer M1-2 is in the direction) to the display area DA which is the second area (in +x direction), with respect to the center of the first opening. The end M1-2a of the first-2 metal layer M1-2 in the direction to the center of the first opening may protrude from the first upper layer 209a and be within the first opening.

This structure allows for a set of the second interlayer insulating layer 207 which is the lower layer, the first upper layer 209a, the first-1 metal layer M1-1, and the first-2 metal layer M1-2 to form (or define) the first groove G1 as illustrated in FIGS. 14 and 15.

In this way, the end M1-1b of the first-1 metal layer M1-1 in the direction to the center of the first opening may protrude from the first upper layer 209a and be within the first opening, and the end M1-2a of the first-2 metal layer M1-2 in the direction to the center of the first opening may protrude from the first upper layer 209a and be within the first opening. Therefore, the first groove G1 formed (or defined) by the set of the second interlayer insulating layer 207 which is the lower layer, the first upper layer 209a, the first-1 metal layer M1-1, and the first-2 metal layer M1-2, may be understood to have the undercut structure. The end M1-1b of the first-1 metal layer M1-1 protruding from the first upper layer 209a may be referred to as the protruding tip, and the length of the protruding tip protruding from the first upper layer 209a may be about 0.3 μm to about 0.5 μm. For example, the length of the protruding tip of the first-1 metal layer M1-1 protruding from the first upper layer 209a may be about 0.4 μm. The length of the end M1-2a of the first-2 metal layer M1-2 protruding from the first upper layer 209a may also be about 0.3 μm to about 0.5 μm. For example, the length of the protruding tip of the first-2 metal layer M1-2 protruding from the first upper layer 209a may be about 0.4 μm.

In the case of the first-1 metal layer M1-1 in the direction to the opening area OA (in −x direction) with respect to the center of the first groove G1, which is formed or arranged by the first opening closest to the opening area OA, the end M1-1a of the first-1 metal layer in the direction to the opening area OA (in −x direction) may be arranged on the second interlayer insulating layer 207, which may be referred to as the lower layer. The bonding force between the first metal layer M1-1 including metal and the inorganic insulating layer may be stronger than the bonding force between the first metal layer M1-1 including metal and the organic insulating layer. As described in one or more embodiments, because the second interlayer insulating layer 207 includes an inorganic insulating (e.g., electrically insulating) material, the end M1-1a of the first-1 metal layer M1-1 in the direction to the opening area OA (in −x direction) may be strongly bonded to the second interlayer insulating layer 207. This may prevent or minimize or reduce defects, such as delamination between layers near the opening area OA.

The second groove G2, which is the second closest to the opening area OA where the through-hole of the substrate 100 is arranged, among the grooves G1, G2, and G in the intermediate area MA which may be referred to as the first area, may be formed or arranged by a second opening formed (or defined) in the second upper layer 209b arranged over the second interlayer insulating layer 207 which may be referred to as the lower layer. The second upper layer 209b may be a part of the first organic insulating layer 209. In one or more embodiments, the second upper layer 209b may be formed or arranged concurrently (e.g., simultaneously) with the first organic insulating layer 209 using substantially the same material during the manufacturing process such that the second upper layer 209b is apart from the first organic insulating layer 209 to be arranged between the display area DA and the first upper layer 209a. The second upper layer 209b may be apart (or separated) from the first upper layer 209a. The second groove G2 may extend along at least a portion of the opening area OA or may encircle (e.g., may be around or may surround) the opening area OA as described in one or more embodiments with reference to FIG. 10.

A second-1 metal layer M2-1 may be arranged over the second upper layer 209b and the second interlayer insulating layer 207 which may be referred to as the lower layer. The second-1 metal layer M2-1 may be formed or arranged concurrently (e.g., simultaneously) with the contact metal layer CM using substantially the same material during the manufacturing process. The second-1 metal layer M2-1 may be in the direction to the opening area OA where the through-hole 10H is arranged (in −x direction), with respect to the center of the second opening defined in the second upper layer 209b. The end M2-1a of the second-1 metal layer M2-1 in the direction to the center of the second groove G2 may protrude from the second upper layer 209b and be within the second opening.

A second-2 metal layer M2-2 which is apart from the second-1 metal layer M2-1 may be arranged over the second upper layer 209b and the second interlayer insulating layer 207 which may be referred to as the lower layer, such that the second-2 metal layer M2-2 is in the direction to the display area DA which is the second area (in +x direction), with respect to the center of the second opening. The end M2-2a of the second-2 metal layer M2-2 in the direction to the center of the second opening may protrude from the second upper layer 209b and be within the second opening.

This structure allows for a set of the second interlayer insulating layer 207, the second upper layer 209b, the second-1 metal layer M2-1, and the second-2 metal layer M2-2 to form (or define) the second groove G1 as illustrated in FIGS. 14 and 15.

In this way, the end M2-1b of the second-1 metal layer M2-1 in the direction to the center of the second opening may protrude from the second upper layer 209b and be within the second opening, and the end M2-2a of the second-2 metal layer M2-2 in the direction to the center of the second opening may protrude from the second upper layer 209b and be within the second opening. Therefore, if (e.g., when) considering a set of the second interlayer insulating layer 207, the second upper layer 209b, the second-1 metal layer M2-1, and the second-2 metal layer M2-2, the second groove G2 may be understood to have the undercut structure. The end M2-1b of the second-1 metal layer M2-1 protruding from the second upper layer 209b may be referred to as the protruding tip, and the length of the protruding tip protruding from the second upper layer 209b may be about 0.3 μm to about 0.5 μm. For example, the length of the protruding tip of the second-1 metal layer M2-1 protruding from the second upper layer 209b may be about 0.4 μm. The length of the end M2-2a of the second-2 metal layer M2-2 protruding from the second upper layer 209b may also be about 0.3 μm to about 0.5 μm. For example, the length of the protruding tip of the second-2 metal layer M2-2 protruding from the second upper layer 209b may be about 0.4 μm.

As illustrated in FIGS. 14 and 15, the first-2 metal layer M1-2 and the second-1 metal layer M2-1 may be integrally formed or provided as a single body. Therefore, the first-2 metal layer M1-2 and the second-1 metal layer M2-1 which are integrally formed or provided as a single body may contact the second interlayer insulating layer 207, which may be referred to as the lower layer, between the first upper layer 209a and the second upper layer 209b. The metal layer and the second interlayer insulating layer 207 which are in contact with each other between the first upper layer 209a and the second upper layer 209b may form or arrange an inorganic contact region (ICR) with strong bonding force. As described in one or more embodiments, the end M1-1a of the first-1 metal layer M1-1 in the direction to the opening area OA (in −x direction) may also come into contact with the second interlayer insulating layer 207 to form or arrange an inorganic contact area ICR with strong bonding strength.

The first groove G1 and the second groove G2 formed (or defined) by the first opening, the second opening, and/or the like may be between the second partitioning wall PW2 and the opening area OA. As illustrated in FIG. 14, openings each of which has substantially the same or similar shape as the second opening may be between the first partitioning wall PW1 and the second partitioning wall PW2, and openings each of which has substantially the same or similar shape as the second opening may be between the first partitioning wall PW1 and the second area, e.g., the display area DA. In such openings, metal layers 210 having a shape similar to a structure in which the first-2 metal layer M1-2 and the second-1 metal layer M2-1 are integrally formed or provided as a single body and arranged on the first organic insulating layer 209 exist so that tips protruding into the openings may be formed or arranged. Through this structure, grooves may be formed (or defined) in one or more suitable locations.

For description for other components and effects, the description for one or more embodiments as described with reference to FIGS. 11 and 12 may be applied.

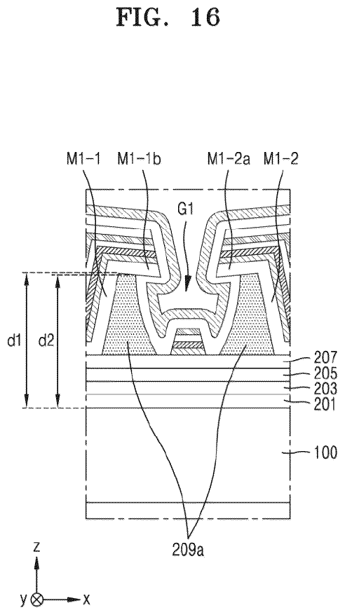

FIG. 16 is a cross-sectional view schematically illustrating a part of the display panel 10 according to one or more embodiments, e.g., the vicinity of the first groove G1. As illustrated in FIG. 16, an upper surface of the first upper layer 209a may have a shape that is inclined with respect to the upper surface of the substrate 100. For example, a distance from the upper surface of the substrate 100 to the upper surface of the first upper layer 209a may decrease as measured moving from a part farther from the center of the first opening to the center of the first opening. In one or more embodiments, the distance from the upper surface of the substrate 100 to the upper surface of the first upper layer 209a at an end of the first upper layer 209a in the direction to the center of the first opening may be less than the distance from the upper surface of the substrate 100 to the upper surface of the first upper layer 209a at an end of the first upper layer 209a in a direction away from the first opening. As the upper surface of the first upper layer 209a has such a shape, a portion of the first-1 metal layer M1-1 on the upper surface of the first upper layer 209a and the end M1-1b within the first opening may have a shape that is inclined toward the inside of the first opening. Similarly, a portion of the first-2 metal layer M1-2 on the upper surface of the first upper layer 209a and the end M1-2a within the first opening may have a shape that is inclined toward the inside of the first opening.

Because the first-1 metal layer M1-1 and the first-2 metal layer M1-2 have such a shape, even if (e.g., when) the bonding force between the first-1 metal layer M1-1 and the first upper layer 209a and the bonding force between the first-2 metal layer M1-2 and the first upper layer 209a are low, the possibility of delamination of the first-1 metal layer M1-1 and the first-2 metal layer M1-2 from the first upper layer 209a may be further reduced, thereby reducing the defect occurrence. This structure may be also applied to grooves G between the display area DA and the first partitioning wall PW1 or to grooves G between the first partitioning wall PW1 and the second partitioning wall PW2. In one or more embodiments, by applying this structure to the grooves G between the display area DA and the first partitioning wall PW1, it may be feasible to effectively or suitably prevent the metal layer 210 and/or the like from being delaminated (or reduce a degree to or occurrence of which the metal layer 210 and/or the like is delaminated) during the process of applying the material for forming or arranging the organic encapsulation layer 320. For example, the inclined structure of the first upper layer and the corresponding shape of the first-1 and first-2 metal layers around the first opening enhance the mechanical anchoring of the metal layers. This design reduces the risk of delamination, even if (e.g., when) the bonding strength between the metal and insulating layers is relatively low. By directing the metal tips inward toward the opening, the structure improves or enhances adhesion and stability during encapsulation processes. Applying this configuration or arrangement to grooves near the display area and partitioning walls further reduces the likelihood of defects, for example, during the formation of the organic encapsulation layer, thereby contributing to a more robust and reliable display panel.

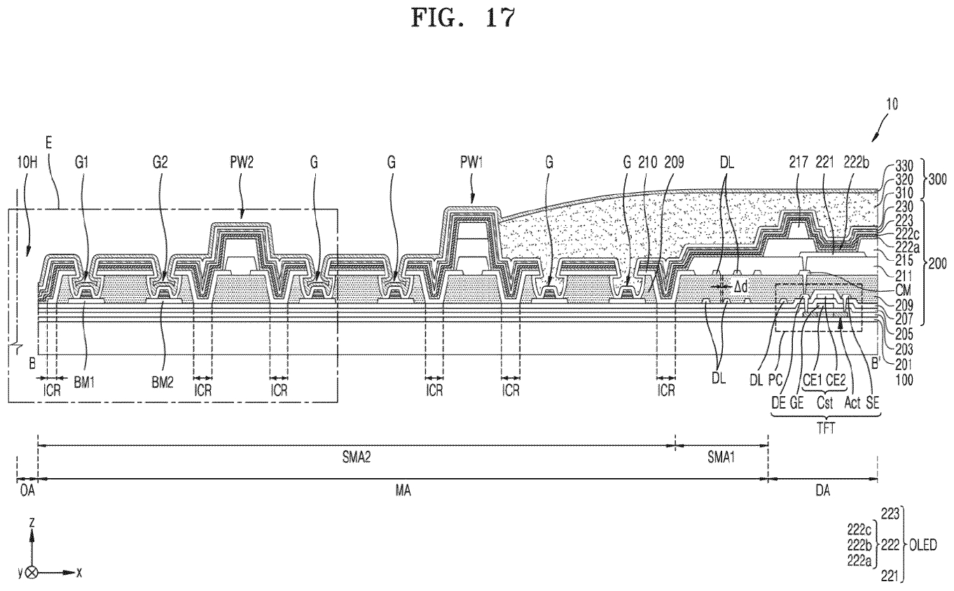

FIG. 17 is a cross-sectional view schematically illustrating a portion of a display panel 10 according to one or more embodiments, and FIG. 18 is an enlarged cross-sectional view illustrating a portion E of the display panel 10 of FIG. 17.

Unlike the display panel 10 and the electronic apparatus 1 having substantially the same display panel 10 according to one or more embodiments with reference to FIGS. 14 and 15, the display panel 10 and the electronic apparatus 1 having substantially the same display panel 10 according to one or more embodiments may further include a first lower metal layer BM1 in the intermediate area MA which is the first area. The first upper layer 209a may be arranged over the second interlayer insulating layer 207 which is the lower layer so as to cover (e.g., such that the first upper layer 209a covers) an edge of the first lower metal layer BM1, and the first opening defined in the first upper layer 209a may expose a central portion of the first lower metal layer BM1. The materials to form the intermediate layer 222, the common electrode 223, and the capping layer 230 may be arranged on the central portion of the first lower metal layer BM1. The first inorganic encapsulation layer 310, the second inorganic encapsulation layer 330, and/or the like may be arranged over the central portion of the first lower metal layer BM1 exposed by the first opening.

The first-1 metal layer M1-1 may be arranged over the second interlayer insulating layer 207, which may be referred to as the lower layer, and the first upper layer 209a. The first metal layer M1-1 may be formed or arranged concurrently (e.g., simultaneously) with the contact metal layer CM using substantially the same material during the manufacturing process. The first-1 metal layer M1-1 may be in the direction to the opening area OA where the through-hole 10H is arranged (in −x direction), with respect to the center of the first opening defined in the first upper layer 209a. The end M1-1a of the first-1 metal layer M1-1 in the direction to the opening area OA (in −x direction) may be arranged on the second interlayer insulating layer 207, which may be referred to as the lower layer, and the end M1-1b of the first-1 metal layer M1-1 in the direction to the center of the first opening may protrude from the first upper layer 209a and be within the first opening.

In one or more embodiments, the first-2 metal layer M1-2, which is apart from the first-1 metal layer M1-1, may be arranged over the first upper layer 209a so as to be in the direction (e.g., such that the first-2 metal layer M1-2 is in the direction) to the display area DA which is the second area (in +x direction), with respect to the center of the first opening. The end M1-2a of the first-2 metal layer M1-2 in the direction to the center of the first opening may protrude from the first upper layer 209a and be within the first opening.

Through this structure, a set of the first lower metal layer BM1, the first upper layer 209a, the first-1 metal layer M1-1, and the first-2 metal layer M1-2 may form (or define) the first groove G1 as illustrated in FIGS. 17 and 18. For reference, if (e.g., when) viewed in the direction perpendicular (e.g., substantially perpendicular) to the substrate 100, the first lower metal layer BM1 may have a ring shape (e.g., a substantially ring shape) that encircles (e.g., is around or surrounds) the opening area OA.

If (e.g., when) the first lower metal layer BM1 does not exist, if (e.g., when) the first opening is formed or arranged in the first upper layer 209a, the second interlayer insulating layer 207 which is the lower layer below the first upper layer 209a may be damaged. However, because the display panel 10 according to one or more embodiments and the electronic apparatus 1 having substantially the same display panel 10 include the first lower metal layer BM1 at a location where the first opening is to be formed or arranged, it may be feasible to effectively or suitably prevent or minimize or reduce damage of the second interlayer insulating layer 207 and/or the like due to excessive or substantial etching occurring during the process of forming or arranging the first opening in the first upper layer 209a.

In this way, the end M1-1b of the first-1 metal layer M1-1 in the direction to the center of the first opening may protrude from the first upper layer 209a and be within the first opening, and the end M1-2a of the first-2 metal layer M1-2 in the direction to the center of the first opening may protrude from the first upper layer 209a and be within the first opening. Therefore, the first groove G1 formed or arranged (or defined) by the set of the first lower metal layer BM1 which is the lower layer, the first upper layer 209a, the first-1 metal layer M1-1, and the first-2 metal layer M1-2, may be understood to have the undercut structure. The end M1-1b of the first-1 metal layer M1-1 protruding from the first upper layer 209a may be referred to as the protruding tip, and the length of the protruding tip protruding from the first upper layer 209a may be about 0.3 μm to about 0.5 μm. For example, the length of the protruding tip of the first-1 metal layer M1-1 protruding from the first upper layer 209a may be about 0.4 μm. The length of the end M1-2a of the first-2 metal layer M1-2 protruding from the first upper layer 209a may also be about 0.3 μm to about 0.5 μm. For example, the length of the protruding tip of the first-2 metal layer M1-2 protruding from the first upper layer 209a may be about 0.4 μm.

In the case of the first-1 metal layer M1-1 in the direction to the opening area OA (in −x direction) with respect to the center of the first groove G1, the end M1-1a of the first-1 metal layer in the direction to the opening area OA (in −x direction) may be arranged on the second interlayer insulating layer 207, which may be referred to as the lower layer. The bonding force between the first metal layer M1-1 including metal and the inorganic insulating layer may be stronger than the bonding force between the first metal layer M1-1 including metal and the organic insulating layer. As described in one or more embodiments, because the second interlayer insulating layer 207 includes an inorganic insulating (e.g., electrically insulating) material, the end M1-1a of the first-1 metal layer M1-1 in the direction to the opening area OA (in −x direction) may be strongly bonded to the second interlayer insulating layer 207. This may prevent or minimize or reduce defects, such as delamination between layers near the opening area OA.

The second groove G2, which is the second closest to the opening area OA where the through-hole of the substrate 100 is arranged, among the grooves G1, G2, and G in the intermediate area MA which may be referred to as the first area, may be formed or arranged by a second lower metal layer BM2, the second upper layer 209b, and/or the like.

For example, the second lower metal layer BM2 arranged over the second interlayer insulating layer 207 which may be referred to as the lower layer, may be between the display area DA which is the second area and the first lower metal layer BM1. An edge of the second lower metal layer BM2 in a direction to the first lower metal layer BM1 may be covered by the first upper layer 209a. The second upper layer 209b arranged over the second interlayer insulating layer 207 may be apart from the first upper layer 209a to define a space between the second upper layer 209b and the first upper layer 209a. The second upper layer 209b may cover an edge of the second lower metal layer BM2 in the direction to the display area DA (in +x direction). Accordingly, a central portion of the second lower metal layer BM2 may be exposed by the space between the first upper layer 209a and the second upper layer 209b. The second upper layer 209b may be a part of the first organic insulating layer 209. In one or more embodiments, the second upper layer 209b may be formed or arranged concurrently (e.g., simultaneously) with the first organic insulating layer 209 during the manufacturing process using substantially the same material, such that the second upper layer 209b is apart from the first organic insulating layer 209 to be arranged between the display area DA and the first upper layer 209a.

The end M1-2b of the first-2 metal layer M1-2 arranged over the first upper layer 209a in the direction to the display area DA (in +x direction) may protrude from the first upper layer 209a and be within the space between the first upper layer 209a and the second upper layer 209b. A second metal layer M2 may be arranged over the second upper layer 209b. The second metal layer M2 may be formed or arranged concurrently (e.g., simultaneously) with the contact metal layer CM using substantially the same material during the manufacturing process. An end M2a of the second metal layer M2 in a direction to the space between the first upper layer 209a and the second upper layer 209b may protrude from the second upper layer 209b and be within the space between the first upper layer 209a and the second upper layer 209b. Accordingly, a set of the second lower metal layer BM2, the first upper layer 209a, the second upper layer 209b, the first-2 metal layer M1-2, and the second metal layer M2 may form or define the second groove G2 as illustrated in FIGS. 17 and 18. This second groove G2 may extend along at least a portion of the opening area OA or may encircle (e.g., may be around or may surround) the opening area OA as described in one or more embodiments with reference to FIG. 10. For example, if (e.g., when) viewed in the direction perpendicular (e.g., substantially perpendicular or normal or in plan view) to the substrate 100, the second lower metal layer BM2 may have a ring shape (e.g., a substantially ring shape) that encircles (e.g., is around or surrounds) the opening area OA.

In this way, the end M1-2b of the first-2 metal layer M1-2 in the direction to the space between the first upper layer 209a and the second upper layer 209b (in +x direction) may protrude from the first upper layer 209a and be within the space between the first upper layer 209a and the second upper layer 209b, and the end M2a of the second metal layer M2 in the direction to the space between the first upper layer 209a and the second upper layer 209b (in −x direction) may protrude from the first upper layer 209a and be within the space between the first upper layer 209a and the second upper layer 209b. Therefore, if (e.g., when) considering a set of the second lower metal layer BM2, the first upper layer 209a, the second upper layer 209b, the first-2 metal layer M1-2, and the second metal layer M2, the second groove G2 may be understood to have an undercut structure. The end M1-2b of the first-2 metal layer M1-2 protruding from the first upper layer 209a may be referred to as the protruding tip, and the length of the protruding tip protruding from the first upper layer 209a may be about 0.3 μm to about 0.5 μm. For example, the length of the protruding tip of the first-2 metal layer M1-2 protruding from the first upper layer 209a may be about 0.4 μm. A length of the end M2a of the second metal layer M2 protruding from the second upper layer 209b may also be about 0.3 μm to about 0.5 μm. For example, the length of the protruding tip of the second metal layer M2 protruding from the second upper layer 209b may be about 0.4 μm.

As described in one or more embodiments, the first lower metal layer BM1 and the second lower metal layer BM2 may contact the second interlayer insulating layer 207 which is the lower layer. In one or more embodiments, each of the first lower metal layer BM1 and the second lower metal layer BM2 may form or arrange a strong inorganic contact region ICR with the second interlayer insulating layer 207. As described in one or more embodiments, the end M1-1a of the first-1 metal layer M1-1 in the direction to the opening area OA (in −x direction) may also come into contact with the second interlayer insulating layer 207 to form or arrange an inorganic contact area ICR with strong bonding strength.

The first groove G1 and the second groove G2 may be between the second partitioning wall PW2 and the opening area OA. As illustrated in FIG. 17, the structures each of which has substantially the same or similar structure of the first upper layer 209a having the first opening, the second upper layer 209b apart from the first upper layer 209a, and/or the like may be between the first partitioning wall PW1 and the second partitioning wall PW2, and the structures each of which has substantially the same or similar structure of the first upper layer 209a having the first opening, the second upper layer 209b apart from the first upper layer 209a, and/or the like may be between the first partitioning wall PW1 and the display area DA which is the second area. Each of the structures may include metal layers having a shape substantially identical to or similar to the first-1 metal layer M1-1, the first-2 metal layer M1-2, and/or the second metal layer M2, such that tips are formed or arranged.

For description for other components and effects, the description for one or more embodiments as described with reference to FIGS. 14 and 15 may be applied.

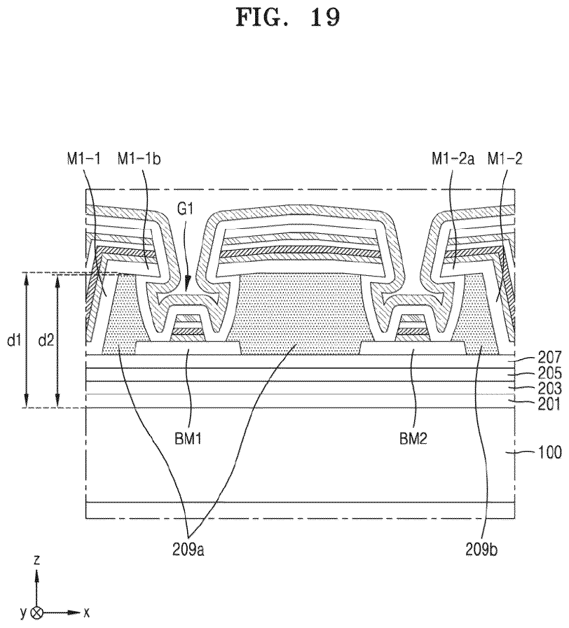

FIG. 19 is a cross-sectional view schematically illustrating a portion of a display panel 10 according to one or more embodiments, e.g., the vicinity of the first groove G1. As illustrated in FIG. 19, an upper surface of the first upper layer 209a may have a shape that is inclined with respect to the upper surface of the substrate 100. For example, a distance from the upper surface of the substrate 100 to the upper surface of the first upper layer 209a, in a portion where the upper surface of the first upper layer 209a contacts the first-1 metal layer M1-1, may decrease as measured moving from a part farther from the center of the first opening to the center of the first opening.

In one or more embodiments, in the portion where the upper surface of the first upper layer 209a contacts the first-1 metal layer M1-1, the distance d2 from the upper surface of the substrate 100 to the upper surface of the first upper layer 209a at an end of the first upper layer 209a in the direction to the center of the first opening may be less than the distance d1 from the upper surface of the substrate 100 to the upper surface of the first upper layer 209a at an end of the first upper layer 209a in the direction away from the first opening. As the upper surface of the first upper layer 209a has such a shape, a portion of the first-1 metal layer M1-1 on the upper surface of the first upper layer 209a and the end M1-1b within the first opening may have a shape that is inclined toward the inside of the first opening. Similarly, a portion of the first-2 metal layer M1-2 on the upper surface of the first upper layer 209a and the end M1-2a within the first opening may have a shape that is inclined toward the inside of the first opening.

Because the first-1 metal layer M1-1 and the first-2 metal layer M1-2 have such a shape, even if (e.g., when) the bonding force between the first-1 metal layer M1-1 and the first upper layer 209a and the bonding force between the first-2 metal layer M1-2 and the first upper layer 209a are low, the possibility of delamination of the first-1 metal layer M1-1 and the first-2 metal layer M1-2 from the first upper layer 209a may be further reduced, thereby reducing the defect occurrence. This may be also applied to the first-2 metal layer M1-2 and the second metal layer M2 for the second groove G2.

This structure may be also applied to grooves G between the display area DA and the first partitioning wall PW1 or to grooves G between the first partitioning wall PW1 and the second partitioning wall PW2. In one or more embodiments, by applying this structure to the grooves G between the display area DA and the first partitioning wall PW1, it may be feasible to effectively or suitably prevent the metal layer 210 and/or the like from being delaminated (or reduce a degree to or occurrence of which the metal layer 210 and/or the like is delaminated) during the process of applying the material for forming or arranging the organic encapsulation layer 320.

So far, the structure of the display panel 10 has been mainly or predominantly described, but embodiments of the present disclosure are not limited thereto. The electronic apparatus 1 including a display panel 10 as described in one or more embodiments may also be said to fall within the scope of the present disclosure.

The light-emitting element, the display apparatus/device, the electronic apparatus/device, the manufacturing apparatuses thereof, or any other relevant apparatuses/devices or components according to one or more embodiments of the present disclosure may be implemented utilizing any suitable hardware, firmware (e.g., an application-specific integrated circuit), software, or a combination of software, firmware, and hardware. For example, the one or more components of the device may be formed or provided on one integrated circuit (IC) chip or on separate IC chips. Further, the one or more components of the device may be implemented on a flexible printed circuit film, a tape carrier package (TCP), a printed circuit board (PCB), or formed or provided on one substrate. Further, the one or more components of the device may be a process or thread, running on one or more processors, in one or more computing devices, executing computer program instructions and interacting with other system components for performing the one or more suitable functionalities as described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

The present disclosure has been described with reference to one or more embodiments as illustrated in the accompanying drawings, which are merely examples. Those of ordinary skill in the art will fully understand that one or more suitable modifications and other equivalent embodiments may be made from the presented embodiments. Therefore, the scope of the present disclosure should be determined by the appended claims and equivalents thereof.

According to one or more embodiments, a display panel with a low defect rate and an electronic apparatus having substantially the same display panel may be implemented. However, the scope of the present disclosure is not limited by the above effects.

It should be understood that embodiments described herein should be considered in a descriptive sense only and not for purposes of limitation. Descriptions of features or aspects within each embodiment should be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A display panel comprising:
a substrate comprising a through-hole, a first region outside the through-hole, and a second region outside the first region;
a display element over the substrate such that the display element is in the second region;
a lower layer corresponding to the first region and the second region and arranged between the substrate and the display element;
a first upper layer over the lower layer in the first region and having a first groove;
a first-1 metal layer over the lower layer and the first upper layer such that the first-1 metal layer is in a direction to the through-hole with respect to a center of the first groove, wherein
an end of the first-1 metal layer in the direction to the through-hole is over the lower layer, and
an end of the first-1 metal layer in a direction to the center of the first groove protrudes from the first upper layer and is within the first groove; and
a first-2 metal layer over the lower layer and the first upper layer such that the first-2 metal layer is in a direction to the second region with respect to the center of the first groove, wherein
an end of the first-2 metal layer in the direction to the center of the first groove protrudes from the first upper layer and is within the first groove.

2. The display panel as claimed in claim 1, wherein the first groove is a groove closest to the through-hole among grooves in the first region.

3. The display panel as claimed in claim 1, further comprising:
a second upper layer arranged over the lower layer in the first region and between the second region and the first upper layer and having a second groove;
a second-1 metal layer over the lower layer and the second upper layer such that the second-1 metal layer is in the direction to the through-hole with respect to a center of the second groove, wherein
an end of the second-1 metal layer in a direction to the center of the second groove protrudes from the second upper layer and is within the second groove; and
a second-2 metal layer over the lower layer and the second upper layer such that the second-2 metal layer is in the direction to the second region with respect to the center of the second groove, wherein
an end of the second groove in the direction to the center of the second groove protrudes from the second upper layer and is within the second groove.

4. The display panel as claimed in claim 3, wherein the first-2 metal layer and the second-1 metal layer are integrally provided as a single body.

5. The display panel as claimed in claim 4, wherein the first-2 metal layer and the second-1 metal layer contact the lower layer between the first upper layer and the second upper layer.

6. The display panel as claimed in claim 1, wherein a distance from an upper surface of the substrate to an upper surface of the first upper layer decreases as measured moving from a part farther from the center of the first groove to the center of the first groove.

7. The display panel as claimed in claim 1, wherein a distance from an upper surface of the substrate to an upper surface of the first upper layer at an end of the first upper layer in the direction to the center of the first groove is less than a distance from the upper surface of the substrate to the upper surface of the first upper layer at an end of the first upper layer in a direction away from the first groove.

8. A display panel comprising:
a substrate comprising a through-hole, a first region outside the through-hole, and a second region outside the first region;
a display element over the substrate such that the display element is in the second region;
a lower layer corresponding to the first region and the second region and arranged between the substrate and the display element;
a first upper layer arranged over the lower layer in the first region and having a first opening exposing the lower layer;
a first-1 metal layer over the lower layer and the first upper layer such that the first-1 metal layer is in a direction to the through-hole with respect to a center of the first opening, wherein
an end of the first-1 metal layer in the direction to the through-hole is over the lower layer, and
an end of the first-1 metal layer in a direction to the center of the first opening protrudes from the first upper layer and is within the first opening; and
a first-2 metal layer over the lower layer and the first upper layer such that the first-2 metal layer is in a direction to the second region with respect to the center of the first opening, wherein
an end of the first-2 metal layer in the direction to the center of the first opening protrudes from the first upper layer and is within the first opening.

9. The display panel as claimed in claim 8, wherein the first opening is an opening closest to the through-hole among openings in the first region.

10. The display panel as claimed in claim 8, further comprising:
a second upper layer arranged over the lower layer in the first region and between the second region and the first upper layer and having a second opening;
a second-1 metal layer over the lower layer and the second upper layer such that the second-1 metal layer in the direction to the through-hole with respect to a center of the second opening, wherein
an end of the second-1 metal layer in a direction to the center of the second opening protrudes from the second upper layer and is within the second opening; and
a second-2 metal layer over the lower layer and the second upper layer such that the second-2 metal layer is in the direction to the second region with respect to the center of the second opening, wherein
an end of the second opening in the direction to the center of the second opening protrudes from the second upper layer and is within the second opening.

11. The display panel as claimed in claim 10, wherein the first-2 metal layer and second-1 metal layer are integrally provided as a single body.

12. The display panel as claimed in claim 11, wherein the first-2 metal layer and the second-1 metal layer contact the lower layer between the first upper layer and the second upper layer.

13. The display panel as claimed in claim 8, wherein a distance from an upper surface of the substrate to an upper surface of the first upper layer decreases as measured moving from a part farther from the center of the first opening to the center of the first opening.

14. The display panel as claimed in claim 8, wherein a distance from an upper surface of the substrate to an upper surface of the first upper layer at an end of the first upper layer in the direction to the center of the first opening is less than a distance from the upper surface of the substrate to the upper surface of the first upper layer at an end of the first upper layer in a direction away from the first opening.

15. A display panel comprising:
a substrate comprising a through-hole, a first region outside the through-hole, and a second region outside the first region;
a display element over the substrate such that the display element is in the second region;
a lower layer corresponding to the first region and the second region and arranged between the substrate and the display element;
a first lower metal layer over the lower layer in the first region;
a first upper layer arranged over the first lower metal layer in the first region to cover an edge of the first lower metal layer and having a first opening exposing a central portion of the first lower metal layer;
a first-1 metal layer over the lower layer and the first upper layer such that the first-1 metal layer is in a direction to the through-hole with respect to a center of the first opening, wherein
an end of the first-1 metal layer in the direction to the through-hole is over the lower layer, and
an end of the first-1 metal layer in a direction to the center of the first opening protrudes from the first upper layer and is within the first opening; and
a first-2 metal layer over the first upper layer such that the first-2 metal layer is in a direction to the second region with respect to the center of the first opening, wherein
an end of the first-2 metal layer in the direction to the center of the first opening protrudes from the first upper layer and is within the first opening.

16. The display panel as claimed in claim 15, wherein the first opening is an opening closest to the through-hole among openings in the first region.

17. The display panel as claimed in claim 15, further comprising:
a second lower metal layer arranged over the lower layer in the first region and between the second region and the first lower metal layer, wherein
an edge of the second lower metal layer in a direction to the first lower metal layer is covered by the first upper layer;
a second upper layer over the lower layer in the first region to cover an edge of the second lower metal layer in the direction to the second region, wherein the second upper layer defines a space between the second upper layer and the first upper layer to expose a central portion of the second lower metal layer; and
a second metal layer over the second upper layer, wherein
an end of the second metal layer in a direction to the space protrudes from the second upper layer and is within the space.

18. The display panel as claimed in claim 17, wherein an end of the first-2 metal layer in the direction to the second region protrudes from the first upper layer and is within the space.

19. The display panel as claimed in claim 15, wherein a distance from an upper surface of the substrate to an upper surface of the first upper layer, in a portion where the upper surface of the first upper layer contacts the first-1 metal layer, decreases as measured moving from a part farther from the center of the first opening to the center of the first opening.

20. An electronic apparatus comprising:
a processor; and
the display panel as claimed in claim 1 configured to be controlled by the processor.
